(19) United States
(12) Patent Application Publication
(10) Pub. No.: US 2021/0167252 A1
(43) Pub. Date: Jun. 3, 2021

(54) SEMICONDUCTOR DEVICE AND MANUFACTURING METHOD THEREFOR

(71) Applicant: LG INNOTEK CO., LTD., Seoul (KR)

(72) Inventor: Youn Joon SUNG, Seoul (KR)

(73) Assignee: LG INNOTEK CO., LTD., Seoul (KR)

(21) Appl. No.: 17/257,220

(22) PCT Filed: Jul. 4, 2019
(86) PCT No.: PCT/KR2019/008236

§ 371 Date: Dec. 30, 2020

(30) Foreign Application Priority Data
Jul. 4, 2018 (KR) 10-2018-0077782
Aug. 21, 2018 (KR) 10-2018-0097598

(51) Int. Cl. H01L 33/38; H01L 33/62; H01L 33/20

(52) U.S. Cl. CPC H01L 33/382; H01L 33/20; H01L 33/62

(57) ABSTRACT

Disclosed in an embodiment is a semiconductor device comprising: a substrate; a semiconductor structure including a first conductive semiconductor layer and a second conductive semiconductor layer, which are arranged on the substrate, an active layer arranged between the first conductive semiconductor layer and the second conductive semiconductor layer, and a recess formed in the second conductive semiconductor layer and the active layer; a first electrode arranged on the semiconductor structure and electrically connected with the first conductive semiconductor layer; a second electrode arranged on the semiconductor structure and electrically connected with the second conductive semiconductor layer; a first pad arranged on the first electrode; and a second pad arranged on the second electrode, wherein the recess separates the second conductive semiconductor layer and the active layer into an active region and an inactive region, the recess extends so as to encompass the active region, and the second pad extends to the top of the recess on the second electrode.

### CROSS REFERENCE TO RELATED APPLICATIONS

This application is the National Phase of PCT International Application No. PCT/KR2019/008236, filed on Jul. 4, 2019, which claims priority under 35 U.S.C. 119(a) to Patent Application Nos. 10-2018-0077782, filed in the Republic of Korea on Jul. 4, 2018, and 10-2018-0097598, filed in the Republic of Korea on Aug. 21, 2018, all of which are hereby expressly incorporated by reference into the present application.

### TECHNICAL FIELD

Embodiments relate to a semiconductor device and a method of manufacturing the same.

### BACKGROUND ART

Semiconductor devices including compounds such as gallium nitride (GaN), aluminum gallium nitride (AlGaN), and the like have many advantages such as a wide and easily adjustable energy band gap and the like and thus can be variously used for light-emitting devices, light-receiving devices, and various diodes.

In particular, a light-emitting device, such as a light-emitting diode or a laser diode, using a III-V group or II-VI group compound semiconductor material can realize various colors, such as red, green, blue, or ultraviolet rays due to the development of thin-film growth technology and device materials. Also, the light-emitting device can realize efficient white light by using a fluorescent material or combining colors and has the advantages of low power consumption, semi-permanent lifetime, fast response time, safety, and environmental friendliness as compared to existing light sources such as fluorescent lamps and incandescent lamps.

Moreover, due to the development of device materials, when a light-receiving device, such as a photodetector or a solar cell, is fabricated using a III-V group or II-VI group compound semiconductor material, the light-receiving device generates a photocurrent by absorbing light in various wavelength regions, and thus it is possible to use light in various wavelength regions from a gamma ray region to a radio wavelength region. In addition, the light-receiving device has the advantages of fast response time, safety, environmental friendliness, and ease of adjustment of device materials and thus may be easily used for power control or ultra-high frequency circuits, or communication modules.

Accordingly, the applications of semiconductor devices are being expanded to transmission modules of optical communication means, light-emitting diode backlights which replace cold cathode fluorescence lamps (CCFLs) constituting backlights of liquid crystal display (LCD) devices, white light-emitting diode lighting devices which may replace fluorescent lamps or incandescent lamps, vehicle headlights, traffic lights, sensors for sensing gas or fire, and the like. In addition, the applications of semiconductor devices may be expanded to high-frequency application circuits, other power control devices, and communication modules.

In particular, a light-emitting device that emits light in an ultraviolet wavelength range may perform a curing or sterilizing action and may be used for curing, medical, and sterilizing purposes.

Recently, research on ultraviolet light-emitting devices has been actively conducted. However, there are problems in that the ultraviolet light-emitting devices are oxidized by delamination and moisture so that light output is reduced. Further, there are problems in that the ultraviolet light-emitting devices are still difficult to realize in a vertical form, and delamination may occur due to voids.

### DISCLOSURE

### Technical Problem

The present invention is directed to providing a flip-chip or vertical type semiconductor device.

The present invention is also directed to providing a semiconductor device with improved reliability due to improved heat dissipation.

The present invention is also directed to providing a semiconductor device with an excellent current-spreading effect.

Objectives to be solved by the embodiment are not limited to the above-described objective and will include objectives and effectiveness which may be identified by solutions for the objectives and the embodiments described below.

### Technical Solution

One aspect of the present invention provides a semiconductor device including a substrate, a semiconductor structure including a first conductive semiconductor layer and a second conductive semiconductor layer, which are disposed on the substrate, an active layer disposed between the first conductive semiconductor layer and the second conductive semiconductor layer, and a recess passing through the second conductive semiconductor layer and the active layer, a first electrode disposed on the semiconductor structure and electrically connected to the first conductive semiconductor layer, a second electrode disposed on the semiconductor structure and electrically connected to the second conductive semiconductor layer, a first pad disposed on the first electrode, and a second pad disposed on the second electrode, wherein the recess divides the second conductive semiconductor layer and the active layer into an active region and an inactive region, the recess is extended and disposed to surround the active region, and the second pad is disposed on the second electrode to extend to an upper portion of the recess.

The recess may include a bottom surface, an inner inclined surface connected to the bottom surface and adjacent to the active region, and an outer inclined surface connected to the bottom surface and facing the inner inclined surface, and one end of the second pad may be disposed to extend on the inner inclined surface of the recess.

The one end of the second pad may be disposed to extend on the bottom surface and the outer inclined surface of the recess.

The second pad may be disposed to extend on the second conductive semiconductor layer in the inactive region, and the one end of the second pad may be disposed between the recess and an outermost side surface of the second conductive semiconductor layer.

The semiconductor structure may include a concave portion to which the first conductive semiconductor layer is exposed, and the concave portion may be disposed to extend from an outer side of the inactive region.

A width ratio of a maximum width of the recess in a horizontal direction and a maximum width of the second conductive semiconductor layer in the inactive region in the horizontal direction may be in a range of 1:0.5 to 1:5.

The semiconductor device may further include a first bump disposed on the first pad, and a second bump disposed on the second pad to be spaced apart from the first bump.

The first electrode may be disposed on the first conductive semiconductor layer in the concave portion, and the second electrode may be disposed on the second conductive semiconductor layer in the active region.

The semiconductor device may further include a first insulating layer disposed on the semiconductor structure, wherein the first insulating layer may be disposed to extend on the first conductive semiconductor layer in the recess and the concave portion from the second conductive semiconductor layer in the active region and to cover the active layer and the exposed second conductive semiconductor layer.

The first insulating layer may be disposed to extend to the first electrode.

The inactive region may be disposed to surround the recess, the active region may be electrically connected to the second electrode, and the inactive region may be electrically separated from the second electrode.

Another aspect of the present invention provides a semiconductor device including a semiconductor structure including a first conductive semiconductor layer, a second conductive semiconductor layer, an active layer disposed between the first conductive semiconductor layer and the second conductive semiconductor layer, and a first recess and a plurality of second recesses passing through the second conductive semiconductor layer and the active layer, a first insulating layer disposed on a lower portion of the semiconductor structure, a first electrode electrically connected to the first conductive semiconductor layer in the plurality of second recesses, a second electrode electrically connected to the second conductive semiconductor layer, an electrode pad disposed outside the semiconductor structure and electrically connected to the second electrode, a first conductive layer configured to electrically connect the second electrode and the electrode pad, and a first insulating layer disposed between the first conductive layer and the second recess, wherein the first recess is disposed to extend adjacent to an edge of the semiconductor structure, the first insulating layer includes a first-first insulating layer disposed at a position corresponding to the first recess and a first-second insulating layer disposed at a position corresponding to the outside of each of the first recess and the second recess, and a thickness of the first-first insulating layer at a central portion of the first recess is greater than a thickness of the first-second insulating layer and less than a height of the first recess.

The thickness of the first-first insulating layer may be reduced toward an edge of the first recess.

In the first recess, the width of the first-first insulating layer may be increased toward a lower portion.

The second recess may be disposed further inward than the first recess with respect to an outer side of the semiconductor structure.

The first insulating layer may further include a first-third insulating layer disposed at a position corresponding to the second recess, and a maximum thickness of the first-third insulating layer at a central portion of the second recess may be greater than the thickness of the first-second insulating layer and less than the height of the second recess.

In the second recess, the thickness of the first-third insulating layer may be reduced toward an edge of the second recess.

The semiconductor device may further include a second insulating layer disposed below the second conductive layer, a second conductive layer disposed below the second insulating layer, a bonding layer disposed below the second conductive layer, and a substrate disposed below the bonding layer, wherein the second insulating layer may include a through hole, and the through hole may overlap the first electrode in a vertical direction.

Still another aspect of the present invention provides a method of manufacturing a semiconductor device including growing a semiconductor structure, disposing a first recess and a second recess, which is located inward from the first recess, in the semiconductor structure, disposing a first insulating layer on the semiconductor structure, a first electrode in the second recess, and a second electrode on the semiconductor structure, disposing a first conductive layer on the semiconductor structure and the second electrode, disposing a second insulating layer on the first insulating layer and the second conductive layer, and disposing a second conductive layer, a bonding layer, a substrate, and an electrode pad on the second insulating layer, wherein the disposing of the second insulating layer includes disposing a second insulating layer including a groove on an upper surface thereof at a position corresponding to the second recess, disposing a photoresist in the groove, etching the second insulating layer to remove at least a portion of the groove, and removing the photoresist.

In the disposing of the second insulating layer including the groove on the upper surface thereof, a ratio of a thickness of the insulating layer at a central portion of the second recess and a height of the second recess may be in a range of 1:1.5 to 1:3.

### Advantageous Effects

According to an embodiment, a semiconductor device can be implemented in various forms such as a flip-chip form or a vertical form.

Further, it is possible to manufacture a light-emitting device with improved reliability due to improved heat dissipation.

Further, it is possible to manufacture a semiconductor device with an excellent current spreading effect.

Various advantages and effects of the present invention are not limited to the above description and can be more easily understood through the description of specific embodiments of the present invention.

### DESCRIPTION OF DRAWINGS

FIG. 1 is a plan view of a semiconductor device according to a first embodiment.

FIG. 2 is a cross-sectional view taken along line AA′ in FIG. 1.

FIG. 3A is an enlarged view of portion K in FIG. 2.

FIG. 3B is an enlarged view of portion L in FIG. 3A.

FIG. 4 is a cross-sectional view taken along line BB′ in FIG. 1.

FIG. 5 is a plan view of a semiconductor device according to a second embodiment.

FIG. 6 is a cross-sectional view taken along line CC′ in FIG. 5.

FIG. 7 is a cross-sectional view of a semiconductor device according to a third embodiment.

FIG. 8 is a conceptual diagram of a semiconductor device package according to one embodiment.

FIGS. 9A to 9H are views illustrating a method of manufacturing the semiconductor device according to the first embodiment.

FIG. 10A is a cross-sectional view of a semiconductor device according to a fourth embodiment.

FIG. 10B is a view illustrating a modified example of FIG. 10A.

FIG. 11 is a conceptual diagram of a semiconductor device according to a fifth embodiment.

FIG. 12 is an enlarged view of portion D in FIG. 11.

FIG. 13 is an enlarged view of portion E in FIG. 11.

FIG. 14 is a plan view of the semiconductor device according to the fifth embodiment.

FIG. 15 is an enlarged view of portion K in FIG. 14.

FIG. 16 is a conceptual diagram of a semiconductor device according to a sixth embodiment.

FIG. 17 is a conceptual diagram of a semiconductor device according to a seventh embodiment.

FIG. 18 is a conceptual diagram of a semiconductor device package according to another embodiment.

FIG. 19 is a plan view of the semiconductor device package according to another embodiment.

FIGS. 20A to 20M are sequence diagrams for describing a method of manufacturing the semiconductor device according to the fifth embodiment.

FIGS. 21A to 21M are sequence diagrams for describing a method of manufacturing the semiconductor device according to the sixth embodiment.

### MODES OF THE INVENTION

Hereinafter, exemplary embodiments of the present invention will be described in detail with reference to the accompanying drawings.

However, the technical spirit of the present invention is not limited to some embodiments which will be described and may be embodied in various forms, and one or more elements in the embodiments may be selectively combined and replaced to be used within the scope of the technical spirit of the present invention.

Further, unless clearly and expressly defined herein, the terms (including technical and scientific terms) used in the embodiments of the present invention have the same meaning as commonly understood by one of ordinary skill in the art to which the present invention belongs. It should be further understood that terms, such as those defined in commonly used dictionaries, should be interpreted as having a meaning that is consistent with their meaning in the context of the related art.

Further, the terms used in the embodiments of the present invention are provided only to describe embodiments of the present invention and not for purposes of limitation.

In the present specification, the singular forms include the plural forms unless the context clearly indicates otherwise, and the phrase “at least one element (or one or more elements) of an element A, an element B, and an element C,” should be understood as including the meaning of at least one of all combinations being obtained by combining the element A, the element B, and the element C.

Further, in describing elements of the embodiments of the present invention, the terms such as first, second, A, B, (a), (b), and the like may be used.

These terms are merely for distinguishing one element from another element, and the property, order, sequence, and the like of corresponding elements are not limited by the terms.

In addition, it will be understood that when one element is referred to as being “connected” or “coupled” to another element, the element may not only be directly connected or coupled to another element but may also be connected or coupled to another element through the other element presented between one element and another element.

Further, when one element is referred to as being formed or disposed “on (above)” or “under (below)” another element, the terms “on (above)” or “under (below)” includes both of a case in which the two elements are in direct contact with each other or a case in which one or more elements are (indirectly) formed or disposed between the two elements. In addition, the term “on (above)” or “under (below)” includes a case in which another element is disposed in an upward direction or a downward direction with respect to one element.

A semiconductor structure according to an embodiment of the present invention may output light in an ultraviolet wavelength range. As an example, the semiconductor structure may also output light in a near ultraviolet wavelength range (UV-A), light in a far ultraviolet wavelength range (UV-B), or light in a deep ultraviolet wavelength range (UV-C). The wavelength range may be determined by an aluminum (Al) composition ratio of the semiconductor structure 120. Further, the semiconductor structure may emit light of various wavelengths having different intensities, and a peak wavelength of light, which has the highest intensity relative to other wavelengths, among wavelengths of emitted light may be a wavelength of near ultraviolet light, far ultraviolet light, or deep ultraviolet light.

As an example, the UV-A may have a wavelength in a range of 320 nm to 420 nm, the UV-B may have a wavelength in a range of 280 nm to 320 nm, and the UV-C may have a wavelength in a range of 100 nm to 280 nm.

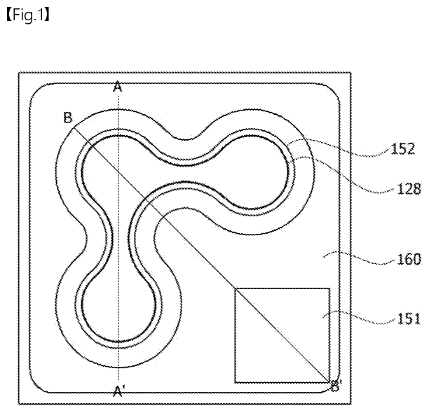

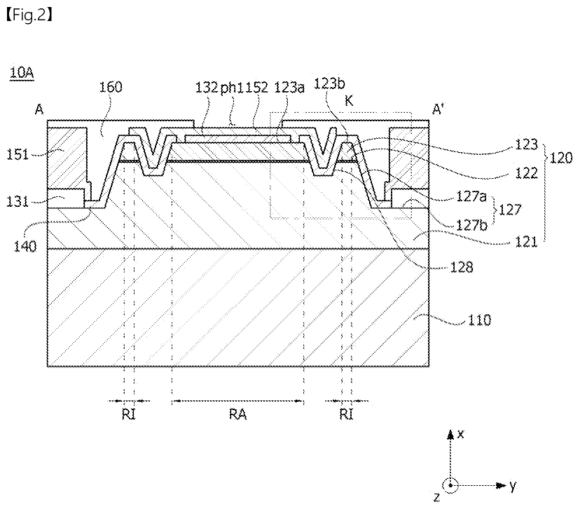

FIG. 1 is a plan view of a semiconductor device according to a first embodiment, and FIG. 2 is a cross-sectional view taken along line AA′ in FIG. 1.

Referring to FIGS. 1 and 2, a semiconductor device 10A according to the first embodiment includes a substrate 110, a semiconductor structure 120 including a first conductive semiconductor layer 121, a second conductive semiconductor layer 123, and an active layer 122, and disposed on the substrate 110, a first insulating layer 140 partially disposed on the semiconductor structure 120, a first electrode 131 electrically connected to the first conductive semiconductor layer 121, a second electrode 132 electrically connected to the second conductive semiconductor layer 123, a first pad 151 disposed on the first electrode 131, a second pad 152 disposed on the second electrode 132, and a second insulating layer 160 partially covering the first insulating layer 140, the first pad 151, and the second pad 152.

First, the substrate 110 may be disposed at one side of the semiconductor device 10A. For example, the substrate 110 may be disposed on a lower portion of the semiconductor device 10A. The substrate 110 may transmit light and may be an insulating substrate 110. The substrate 110 may be made of at least one selected from the group consisting of Al, silicon (Si), oxygen (O), zinc (Zn), magnesium (Mg), gallium (Ga), phosphorus (P), and fluorine (F). Specifically, the substrate 110 may be formed of a material selected from the group consisting of sapphire (Al₂O₃), silicon carbide (SiC), gallium nitride (GaN), zinc oxide (ZnO), Si, gallium phosphide (GaP), indium phosphide (InP), and germanium (Ge), but the material of the substrate 110 is not particularly limited as long as it transmits light generated from the semiconductor structure 120.

Uneven portions may be formed at a lower portion of the substrate 110, and the uneven portions may have a texture structure so that light extraction efficiency may be improved. For example, the semiconductor device 10A may be a flip-type semiconductor device so that light may be emitted upward through the substrate 110, and the amount of light emitted from the inside of the semiconductor device 10A to the outside thereof may be increased due to the uneven portions of the substrate 110. For example, the substrate 110 may be made of a material having a refractive index between 1 and 3.4 in order to minimize total reflection at an interface with the outside. However, the substrate 110 is not limited to such a structure and may have various structures.

The semiconductor structure 120 may include the first conductive semiconductor layer 121, the active layer 122, and the second conductive semiconductor layer 123. In this case, the first conductive semiconductor layer 121, the active layer 122, and the second conductive semiconductor layer 123 may be disposed in a first direction (X-axis direction). Hereinafter, the first direction (X-axis direction), which is a thickness direction of each layer, will be defined as a vertical direction, and a second direction (Y-axis direction) perpendicular to the first direction (X-axis direction) will be defined as a horizontal direction. In addition, a third direction (Z-axis direction) is a direction perpendicular to both the first direction (X-axis direction) and the second direction (Y-axis direction).

The first conductive semiconductor layer 121 may be implemented with a III-V group or II-VI group compound semiconductor and may be doped with a first dopant. The first conductive semiconductor layer 121 may be made of semiconductor materials having a composition formula of Inₓ₁Al_{y1}Ga_{1-x1-y1}N (0<=x1<=1, 0<=y1<=1, and 0<=x1+y1<=1), for example, semiconductor materials selected from among GaN, aluminum gallium nitride (AlGaN), indium gallium nitride (InGaN), indium aluminum gallium nitride (InAlGaN), and the like. In addition, the first dopant may be an n-type dopant such as Si, Ge, Sn, Se, or Te. When the first dopant is an n-type dopant, the first conductive semiconductor layer 121 doped with the first dopant may be an n-type semiconductor layer.

The active layer 122 may be disposed between the first conductive semiconductor layer 121 and the second conductive semiconductor layer 123. The active layer 122 may be a layer at which electrons (or holes) injected through the first conductive semiconductor layer 121 and holes (or electrons) injected through the second conductive semiconductor layer 123 are recombined. In the active layer 122, as the electrons and the holes are recombined, the electrons may transition to a lower energy level and light having a wavelength corresponding to band gap energy of a well layer included in the active layer 122, which will be described below, may be generated. Light of a wavelength having the highest intensity relative to other wavelengths, among wavelengths of light emitted from the semiconductor device, may be ultraviolet rays, and the ultraviolet rays may be near ultraviolet rays, far ultraviolet rays, or deep ultraviolet rays described above.

The active layer 122 may have one structure among a single well structure, a multi-well structure, a single quantum well structure, a multi-quantum well (MQW) structure, a quantum dot structure, and a quantum wire structure, but the structure of the active layer 122 is not limited thereto.

The second conductive semiconductor layer 123 may be formed on the active layer 122 and implemented with a III-V group or II-VI group compound semiconductor, and the second conductive semiconductor layer 123 may be doped with a second dopant. The second conductive semiconductor layer 123 may be made of semiconductor materials having a composition formula Inₓ₅Al_{y2}Ga_{1-x5-y2}N (0<=x5<=1, 0<=y2<=1, and 0<=x5+y2<=1) or materials selected from among aluminum indium nitride (AlInN), aluminum gallium arsenide (AlGaAs), GaP, gallium arsenide (GaAs), gallium arsenide phosphide (GaAsP), and aluminum gallium indium phosphide (AlGaInP). When the second dopant is a p-type dopant such as Mg, Zn, calcium (Ca), strontium (Sr), barium (Ba), or the like, the second conductive semiconductor layer 123 doped with the second dopant may be a p-type semiconductor layer.

Additionally, an electron blocking layer (not shown) may be disposed between the active layer 122 and the second conductive semiconductor layer 123. The electron blocking layer (not shown) may block electrons, which are supplied from the first conductive semiconductor layer 121 to the active layer 122, from flowing out to the second conductive semiconductor layer 123 without being recombined in the active layer 122 to emit light, and thus the recombination probability of electrons and holes in the active layer 122 may be increased. An energy band gap of the electron blocking layer (not shown) may be greater than an energy band gap of the active layer 122 and/or the second conductive semiconductor layer 123.

The electron blocking layer (not shown) may be selected from semiconductor materials having a composition formula of Inₓ₁Al_{y1}Ga_{1-x1-y1}N (0<=x1<=1, 0<=y1<=1, and 0<=x1+y1<=1), for example, semiconductor materials selected from among AlGaN, InGaN, InAlGaN, and the like, but the present invention is not limited thereto. In the electron blocking layer (not shown), a first layer (not shown) having a high Al composition and a second layer (not shown) having a low Al composition may be alternately disposed.

In addition, the first conductive semiconductor layer 121, the active layer 122, and the second conductive semiconductor layer 123 may all include aluminum. Accordingly, the first conductive semiconductor layer 121, the active layer 122, and the second conductive semiconductor layer 123 may each be made of AlGaN. However, the present invention is not necessarily limited thereto.

Further, when the first conductive semiconductor layer 121, the active layer 122, and the second conductive semiconductor layer 123 all include Al, the electron blocking layer (not shown) may have an Al composition of 50% to 90%. When the Al composition of the electron blocking layer (not shown) is less than 50%, a height of an energy barrier for blocking electrons may be insufficient, and light emitted from the active layer 122 may be absorbed by the electron blocking layer (not shown). When the Al composition of the electron blocking layer (not shown) exceeds 90%, electrical characteristics of the semiconductor device may be degraded.

In addition, the semiconductor structure 120 may include a concave portion 127 and a recess 128 that are recessed toward the first conductive semiconductor layer 121 from the second conductive semiconductor layer 123. That is, the concave portion 127 may be disposed to pass through the second conductive semiconductor layer 123 and the active layer 122 and to expose a partial region of the first conductive semiconductor layer 121. In addition, the recess 128 may be disposed to pass through the second conductive semiconductor layer 123 and the active layer 122, and disposed to pass through even a partial region of the first conductive semiconductor layer 121 to expose the first conductive semiconductor layer 121. Accordingly, the partial region of the first conductive semiconductor layer 121 may be exposed by the concave portion 127 and the recess 128.

The concave portion 127 may be disposed to extend from the outside of upper surfaces 123a and 123b of the second conductive semiconductor layer 123 to the outside of the semiconductor device. For example, the concave portion 127 may be disposed further outward than an outermost side of the upper surface of the second conductive semiconductor layer 123. Thus, the concave portion 127 may be disposed in an inactive region RI to be described below. In addition, the concave portion 127 may include an inclined surface 127a and a bottom surface 127b.

Since the inclined surface 127a extends from the outermost side of the upper surface of the second conductive semiconductor layer 123 and passes through the second conductive semiconductor layer 123 and the active layer 122, the inclined surface 127a may include an outermost side surface of the second conductive semiconductor layer 123 and an outermost side surface of the active layer 122. The outermost side surface of the second conductive semiconductor layer 123 and the outermost side surface of the active layer 122 may be disposed further outward than the outermost side of the upper surface of the second conductive semiconductor layer 123.

The outermost side surface of the second conductive semiconductor layer 123 and the outermost side surface of the active layer 122 may be inclined at a predetermined angle with respect to the upper surface of the second conductive semiconductor layer 123. Such an angle may be changed by an etching process.

In addition, the inclined surface 127a may further include an outer side surface of the first conductive semiconductor layer 121 extending along the outermost side surface of the second conductive semiconductor layer 123 and the outermost side surface of the active layer 122. The outer side surface of the first conductive semiconductor layer 121 may extend to have a predetermined height along the outermost side surface of the active layer 122.

In addition, the concave portion 127 may include the bottom surface 127b extending from the inclined surface 127a. The bottom surface 127b may be disposed to have a predetermined angle with the inclined surface 127a, and may have a flat structure in the horizontal direction so that the first electrode 131 to be described later is easily disposed. However, the present invention is not limited thereto.

In addition, the bottom surface 127b is a portion of an upper surface of the first conductive semiconductor layer 121, and may be disposed to be spaced apart from the outermost side surfaces of the active layer 122 and the second conductive semiconductor layer 123.

Further, the concave portion 127 may be disposed outward from the recess 128, which will be described below, to surround the recess 128.

Further, the recess 128 may be extended and disposed adjacent to an edge of the semiconductor structure 120. In particular, the recess 128 may be disposed to extend adjacent to an edge of the active layer 122 or the second conductive semiconductor layer 123. In other words, the recess 128 may be disposed to extend adjacent to the inclined surface 127a of the concave portion 127. In addition, the recess 128 may be disposed to be spaced apart from the concave portion 127, and may be continuously disposed. For example, when the recess 128 is continuously disposed, the recess 128 may be in the form of a closed loop on a plane (ZY plane) in the semiconductor structure 120. Hereinafter, descriptions will be given on the basis of the case in which the recess 128 is in the form of a closed loop.

Accordingly, the semiconductor structure 120 may be divided into an active region RA and the inactive region RI by the recess 128. Here, the active region RA may be located inward from the recess 128 in the semiconductor structure 120, and the inactive region RI may be located outward from the recess 128 in the semiconductor structure 120.

In addition, the active layer 122 of the active region RA and the active layer 122 of the inactive region RI may be disposed to be spaced apart from each other. The active region RA may be an emission region in which the active layer 122 located therein is disposed adjacent to the second electrode 132 and thus electrons and holes are combined. In contrast, the inactive region RI may be a non-emission region in which the active layer 122 located therein is spaced apart from the active layer 122 of the active region RA, and is disposed closer to the edge of the semiconductor structure 120 than the second electrode 132 and thus the combination of electrons and holes does not occur.

With such a configuration, even when the second insulating layer 160 surrounding side and upper surfaces of the semiconductor structure 120 is delaminated or cracked due to heat, which is generated due to light emission of the semiconductor device, external high temperature and high humidity environment, a difference in thermal expansion coefficient between the semiconductor structures 120, and the like, moisture, contaminants, or the like penetrating into the semiconductor structure 120 from the outside may be prevented from oxidizing the active layer 122 of the active region RA, which is an emission region.

Specifically, in the semiconductor device according to the first embodiment, the recess 128 may prevent a direct connection between the active layer 122 of the active region RA and the active layer 122 of the inactive region RI. Accordingly, when the active layer 122 of the inactive region RI adjacent to a sidewall of the semiconductor structure 120 is exposed to the outside due to the above-described delamination, the active layer 122 of the inactive region RI may be oxidized due to the exposure.

However, since the active layers 122 are separated by the recess 128 and disposed in the active region RA and the inactive region RI, even when the active layer 122 of the inactive region RI is oxidized, the active layer 122 of the active region RA may be protected from the oxidation. That is, the recess 128 may protect the oxidation of the active layer 122 of the emission region from external moisture.

In particular, in a case in which the semiconductor device generates ultraviolet light, an energy band gap and an Al concentration of the active layer 122 increase compared to a case in which the semiconductor device generates visible light, and thus the semiconductor device may be more vulnerable to oxidation. Accordingly, when the semiconductor device described herein generates ultraviolet light, reliability may be greatly improved.

Further, when the semiconductor structure 120 generates ultraviolet light, the semiconductor structure 120 has high band gap energy, and thus, in the semiconductor structure 120, current spreading characteristics may be degraded and an effective light-emitting region may be reduced in size.

For example, when the semiconductor structure 120 includes a GaN-based compound semiconductor, in order to emit ultraviolet light, the semiconductor structure may include AlₓGa₍₁₋ₓ₎N (0<=x<=1) containing a large amount of Al. Here, as the value of x indicating the Al content increases, the resistance of the semiconductor structure 120 may also increase, and the current spreading and current injection characteristics of the semiconductor structure 120 may be degraded.

Thus, the current spreading in the semiconductor structure 120 may be carried out in the active region RA. As a result, the semiconductor device 10A described herein may maintain light output even when the recess 128 is included. In addition, as described above, due to the recess 128, the region in which oxidation is carried out by moisture or the like is limited to an outward region (e.g., the active region RA) of the recess 128, so that the active layer 122 located in an effective light-emitting region (e.g., the inactive region RI) may be protected from the oxidation, thereby maintaining the light output. Here, the effective light-emitting region refers to a region which has a light output of at least a predetermined ratio (e.g., 40%) of the maximum light output.

Further, the upper surface of the second conductive semiconductor layer 123 may be divided into a first upper surface 123a and a second upper surface 123b by the recess 128. The first upper surface 123a may be disposed inward from the recess 128, and the second upper surface 123b may be disposed outward from the recess 128. The first upper surface 123a and the second upper surface 123b are disposed to be spaced apart from each other, and may be electrically separated from each other by the recess 128.

The first electrode 131 may be disposed on the first conductive semiconductor layer 121 exposed through a mesa etching process and electrically connected to the first conductive semiconductor layer 121. In particular, the concave portion 127 formed through a mesa etching process may be disposed outward from the recess 128 to surround the recess 128.

Further, the first electrode 131 may be disposed on a low concentration layer of the active layer 122 to secure relatively smooth current injection characteristics. That is, the first electrode 131 may be disposed adjacent to a region of the low concentration layer of the first conductive semiconductor layer 121. This is because a high concentration layer of the first conductive semiconductor layer 121 has a high Al concentration and thus has relatively low current spreading characteristics. However, the present invention is not limited to such a configuration.

In addition, the first electrode 131 may be disposed on the first conductive semiconductor layer 121 located outward from the recess 128. For example, the first electrode 131 may be disposed on the bottom surface 127b of the concave portion 127. In addition, when a current is injected through the first electrode 131, the semiconductor structure 120 may generate light.

The second electrode 132 may be disposed on the second conductive semiconductor layer 123 and may be electrically connected to the second conductive semiconductor layer 123. Further, the second electrode 132 is disposed inward from the recess 128, and thus may overlap the active region RA in the first direction.

The first electrode 131 and the second electrode 132 may be ohmic electrodes. Each of the first electrode 131 and the second electrode 132 may be formed to include at least one among indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—Ga ZnO (AGZO), In—Ga ZnO (IGZO), ZnO, iridium oxide (IrOx), ruthenium oxide (RuOx), nickel oxide (NiO), RuOx/ITO, Ni/IrOx/Au, Ni/IrOx/Au/ITO, silver (Ag), nickel (Ni), chromium (Cr), titanium (Ti), Al, rhodium (Rh), palladium (Pd), iridium (Ir), tin (Sn), indium (In), ruthenium (Ru), Mg, Zn, platinum (Pt), gold (Au), and hafnium (Hf), but the present invention is not limited to the above materials.

The first insulating layer 140 may be disposed on the semiconductor structure 120 to insulate the first electrode 131 from the active layer 122, the second conductive semiconductor layer 123, and the second electrode 132. In addition, the first insulating layer 140 may electrically insulate the second electrode 132 from the active layer 122, the first conductive semiconductor layer 121, and the first electrode 131.

Further, the first insulating layer 140 may be partially disposed on the semiconductor structure 120 to partially expose the first conductive semiconductor layer 121 and the second conductive semiconductor layer 123. Thus, the first electrode 131 and the second electrode 132 may be disposed in the regions exposed by the first insulating layer 140.

In addition, the first insulating layer 140 may prevent external moisture or the like from penetrating into the semiconductor structure 120 from the edge of the semiconductor structure 120 during the process of the semiconductor device 10A, except the regions in which the first electrode 131 and the second electrode 132 are disposed. In particular, the first insulating layer 140 may be disposed in the recess 128 to prevent contaminants or the like from penetrating into the recess 128.

Further, the first insulating layer 140 may be disposed in the recess 128 to maintain insulation between the active layer 122 of the active region RA and the active layer 122 of the inactive region RI.

Further, the first insulating layer 140 may be made of at least one material selected from the group consisting of SiO₂, SiₓO_{y}, Si₃N₄, SiₓN_{y}, SiOₓN_{y}, Al₂O₃, TiO₂, AlN, and the like, but the present invention is not limited thereto. The first insulating layer 140 may be formed as a single-layer or a multi-layer. As an example, the first insulating layer 140 may be a distributed Bragg reflector (DBR) having a multi-layer structure including a Si oxide or a Ti compound. However, the present invention is not necessarily limited thereto, and the first insulating layer 140 may include various reflection structures.

Further, when the first insulating layer 140 performs a reflection function, the first insulating layer 140 may upward reflect light that is upwardly or laterally emitted from the active layer 122, thereby enhancing light extraction efficiency.

In addition, the first pad 151 may be disposed on the first electrode 131. Specifically, the first pad 151 may be disposed to cover an upper surface of the first electrode 131 and to cover a portion of the first insulating layer 140.

Further, the first insulating layer 140 may be partially disposed on the first upper surface 123a of the second conductive semiconductor layer 123. In addition, the first insulating layer 140 may be disposed to extend along the recess 128, the second upper surface 123b, and the concave portion 127 from the first upper surface 123a of the second conductive semiconductor layer 123. That is, the first insulating layer 140 may be disposed to extend along the recess 128 in the active region RA. In addition, the first insulating layer 140 may be disposed to extend up to the bottom surface 127b of the concave portion 127. Accordingly, the first insulating layer 140 may partially overlap the active region RA in the vertical direction. In addition, the first insulating layer 140 may be disposed to overlap the recess 128 in the vertical direction and to partially overlap the inactive region RI in the vertical direction. With such a configuration, moisture or the like is prevented from penetrating into the active layer 122 exposed by the recess 128, and light generated from the active layer 122 of the active region RA may be easily reflected even though the light is laterally emitted. In addition, the active layer 122 of the inactive region RI may also be easily protected from external moisture or the like, so that a phenomenon in which oxidation moves to the active layer 122 of the active region RA through the active layer 122 and the first conductive semiconductor layer 121 of the inactive region RI may be prevented.

In addition, the first pad 151 may be made of a conductive material. For example, the first pad 151 may include at least one from among Ag, Ni, Cr, Ti, Al, Rh, Pd, Ir, Sn, In, Ru, Mg, Zn, Pt, Au, and Hf. However, the present invention is not limited to such a material.

Further, the second pad 152 may be disposed on the second electrode 132. In addition, the upper surface of the first pad 151 and an upper surface of the second pad 152 may be disposed to be coplanar with each other with respect to a lower surface of the semiconductor device 10A. However, the present invention is not limited to such a configuration. That is, a thickness of each of the first pad 151 and the second pad 152 may be adjusted. For example, when the first pad 151 and the second pad 152 are bonded after minimizing the height difference between the upper surface of the first pad 151 and the upper surface of the second pad 152, the generation of voids may be suppressed.

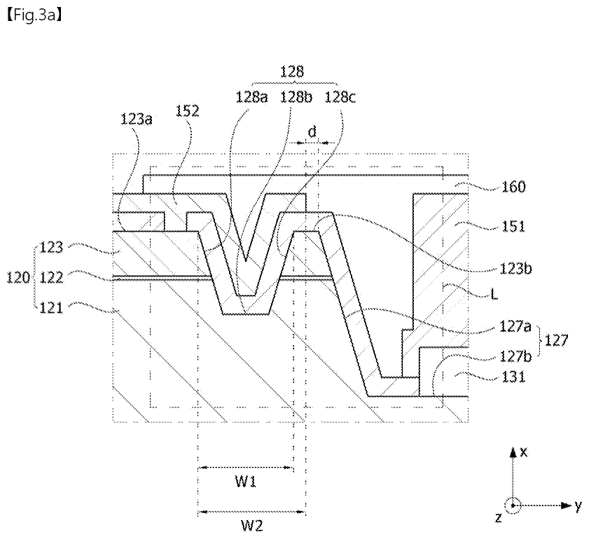

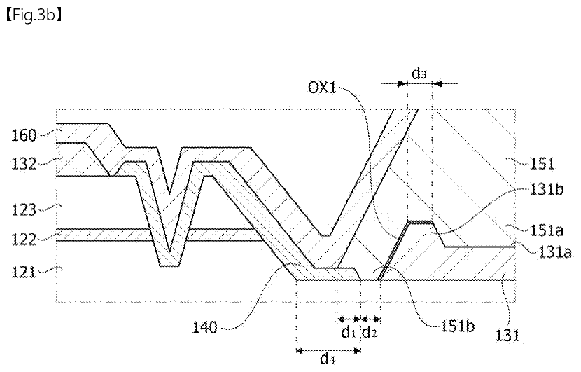

In particular, at least a portion of the second pad 152 may overlap the recess 128 in the first direction. With such a configuration, the second pad 152 may easily protect the active layer 122 of the active region RA from external moisture or the like during delamination. In addition, since the second pad 152 is disposed to extend to the recess 128, heat is easily discharged through the second pad, so that a delamination phenomenon due to heat may be easily prevented. This will be described below in detail with reference to FIGS. 3A and 3B.

Further, the second pad 152 may be partially disposed on the first insulating layer 140. In addition, like the first pad 151, the second pad 152 may be made of a conductive material. For example, the second pad 152 may include at least one from among Ag, Ni, Cr, Ti, Al, Rh, Pd, Ir, Sn, In, Ru, Mg, Zn, Pt, Au, and Hf. However, the present invention is not limited to such a material.

The second insulating layer 160 may be disposed on the semiconductor structure 120, the first insulating layer 140, the first pad 151, and the second pad 152. With such a configuration, the second insulating layer 160 may protect the semiconductor device 10A from the outside.

Specifically, the second insulating layer 160 may be disposed to partially expose the first pad 151. Accordingly, the second insulating layer 160 may be partially disposed on the first pad 151 so that the first pad 151 is partially exposed. Thus, the exposed first pad 151 may be electrically connected to the outside.

Further, the second insulating layer 160 may be partially disposed on the second pad 152 so that the second pad 152 is partially exposed. For example, the second insulating layer 160 may include a first through hole ph1. The first through hole ph1 may be disposed on the second pad 152 to expose a portion of the upper surface of the second pad 152. In addition, the exposed second pad 152 may be electrically connected to the outside.

Further, a portion of the second insulating layer 160 may overlap the recess 128 in the first direction. With such a configuration, the recess 128 is protected by the first insulating layer 140, the second pad 152, and the second insulating layer 160, so that light output may be prevented from being reduced due to the oxidation caused by delamination and moisture in the semiconductor device according to the first embodiment.

In addition, the second insulating layer 160 may be transparent and may be made of an insulating material. For example, the second insulating layer 160 may include at least one selected from the group consisting of SiO₂, SiOₓ, SiOₓN_{y}, Si₃N₄, Al₂O₃, or TiO₂, but the present invention is not limited to such a material.

In addition, the second insulating layer 160 and the first insulating layer 140 may be made of the same material or may be made of different materials. In addition, since the second pad 152 and the second insulating layer 160 are disposed on the first insulating layer 140, defects formed in the first insulating layer 140 may be difficult to propagate to the second insulating layer 160, so that the second insulating layer 160 may serve to shield the propagation of the defects at the interface between the first insulating layer 140 and the second insulating layer 160.

Further, the first insulating layer 140 and the second insulating layer 160 may be formed as one layer by being melted by heat during a process, or an interface between the first insulating layer 160 and the second insulating layer 160 may not exist in at least some regions. Accordingly, even when an observation is performed using transmission electron microscopy (TEM) or the like, the interface between the first insulating layer 140 and the second insulating layer 160 may be seen as one layer in at least some regions. In addition, the first insulating layer 140 and the second insulating layer 160 may be formed by a single process.

Accordingly, it is possible to solve a problem of an increase in cost of the semiconductor device due to a reduction in optical and electrical reliability of the semiconductor device or an extension of a process time for the semiconductor device.

FIG. 3A is an enlarged view of portion K in FIG. 2, and FIG. 3B is an enlarged view of portion L in FIG. 3A.

Referring to FIG. 3A, the recess 128 may include a bottom surface 128b located at a lowermost portion thereof, an inner inclined surface 128a disposed inward from the bottom surface 128b, and an outer inclined surface 128c disposed outward from the bottom surface 128b.

The bottom surface 128b may be located at a lowermost portion of the exposed first conductive semiconductor layer 121 at inner side edges of the active layer 122 or the second conductive semiconductor layer 123.

In addition, the inner inclined surface 128a may be disposed inward from the bottom surface 128b and may extend from the bottom surface 128b to the upper surface of the second conductive semiconductor layer 123. For example, the inner inclined surface 128a may extend from the bottom surface 128b to the first upper surface 123a of the upper surface of the second conductive semiconductor layer 123. That is, the inner inclined surface 128a may be disposed along side surfaces of the first conductive semiconductor layer 121, the active layer 122, and the second conductive semiconductor layer 123, which are located inward from the bottom surface 128b.

The outer inclined surface 128c may be disposed outward from the bottom surface 128b and may extend from the bottom surface 128b to the upper surface of the second conductive semiconductor layer 123. For example, the outer inclined surface 128c may extend from the bottom surface 128b to the second upper surface 123b of the upper surface of the second conductive semiconductor layer 123. Further, the outer inclined surface 128c may be disposed along side surfaces of the first conductive semiconductor layer 121, the active layer 122, and the second conductive semiconductor layer 123, which are located outward from the bottom surface 128b. In addition, the outer inclined surface 128c and the inner inclined surface 128a may be symmetrically disposed with respect to the bottom surface 128b. That is, the outer inclined surface 128c faces the inner inclined surface 128a and may be connected to the bottom surface 128b.

In addition, the second pad 152 may be disposed above the recess 128 such that at least a portion of the second pad 152 overlaps the recess 128 in the first direction. In an embodiment, the second pad 152 may be disposed on the second electrode 132 and extend in the second direction, so that the second pad 152 may also be disposed outside the recess 128. That is, the second pad 152 may be disposed to be spaced apart from an outermost side of the second upper surface 123b of the second conductive semiconductor layer 123 with a separation distance d. For example, one end of the second pad 152 may be disposed between the recess 128 and the concave portion 127, and the separation distance d may be in a range of 3 μm to 7 μm. When the separation distance d is less than 3 μm, the process is difficult to perform. When the separation distance is greater than or equal to 7 μm, a resistance is increased, and thus there is a problem of degrading light extraction.

With such a configuration, the second pad 152 is partially extended to the outside of the recess 128 and disposed, and thus heat is easily discharged through the second pad, thereby solving a delamination problem caused by the expansion due to heat. In addition, the second pad 152 may easily protect the active layer 122 in the active region from external moisture or the like by preventing the second pad 152 from being laminated due to heat.

A maximum width W1 of the recess 128 may be in a range of 1.5 μm to 4.5 μm, and a maximum width W2 of the second pad 152 in the second direction from an innermost portion of the recess 128 may be in a range of 2.5 μm to 7.5 μm. That is, a width ratio of the maximum width W1 of the recess 128 and the maximum width W5 of the second pad 152 in the second direction from the innermost portion of the recess 128 may be in a range of 1:0.5 to 1:5. When the width ratio is less than 1:0.5, delamination may occur and moisture-resistance improvement through the second pad may be degraded. In addition, when the width ratio is greater than 1:5, there is a problem that light output may be reduced due to the second pad.

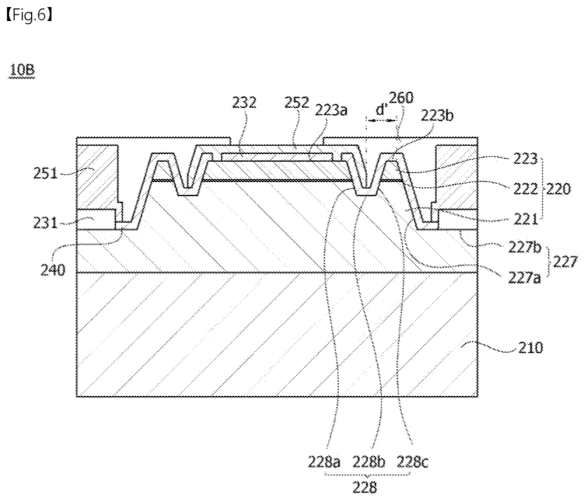

Further, as described above, the second pad 152 may be disposed to extend to various positions above the recess 128. In an embodiment, the second pad 152 may be disposed to extend to the inner inclined surface 128a of the recess 128. Accordingly, one end of the second pad 152 may be located on the inner inclined surface 128a. In another embodiment, the second pad 152 may be disposed to extend to the bottom surface 128b of the recess 128 (see FIG. 6). Thus, one end of the second pad 152 may be located on the bottom surface 128b. In still another embodiment, the second pad 152 may be disposed to extend to the outer inclined surface 128c through the inner inclined surface 128a and the bottom surface 128b. Thus, one end of the second pad 152 may be located on the outer inclined surface 128c. In addition, in yet another embodiment, the second pad 152 may extend to an upper portion of the second conductive semiconductor layer 123 of the inactive region RI through the inner inclined surface 128a, the bottom surface 128b, and the outer inclined surface 128c. Thus, one end of the second pad 152 may be located on the second conductive semiconductor layer 123 of the inactive region RI. As described above, the semiconductor device described herein may be implemented in various embodiments as described above in response to moisture resistance, resistance, or the like of the semiconductor device.

Referring to FIG. 3B, the first electrode 131 may be electrically connected to the first conductive semiconductor layer 121. The first electrode 131 may include a first groove 131a formed on one surface thereof. Unlike a general visible light-emitting device, in the case of an ultraviolet light-emitting device, an electrode needs to be heat-treated at a high temperature for an ohmic contact. As an example, the first electrode 131 and/or the second electrode 132 may be heat treated at a temperature of about 600° C. to 900° C., and in this process, an oxide film OX1 may be formed on a surface of the first electrode 131. Since the oxide film OX1 may act as a resistive layer, an operating voltage may be increased.

The oxide film OX1 may be formed by oxidizing a material constituting the first electrode 131. Thus, in the process of heat-treating the first electrode 131, when components such as concentration and/or weight percentage of the material constituting the first electrode 131 are not constant, or when heat is not uniformly applied to the surface of the first electrode 131 due to other elements, the thickness of the oxide film OX1 may be non-uniformly formed.

Accordingly, in the first electrode 131 according to the embodiment, the oxide film OX1 may be removed by forming the first groove 131a in one surface. In this process, a protrusion 131b surrounding the first groove 131a may be formed.

In the process of heat-treating the first electrode 131, oxidation and/or corrosion may occur in at least some regions of the side surface of each of the first conductive semiconductor layer 121, the active layer 122, and the second conductive semiconductor layer 123, which are exposed between the first electrode 131 and the second electrode 132.

However, according to the embodiment, the first insulating layer 140 may be disposed to extend from a partial region of the upper surface of the second conductive semiconductor layer 123 to a partial region of the first conductive semiconductor layer 121 and the side surface of the active layer 122. In addition, the first insulating layer 140 may be disposed on the side surface of each of the first conductive semiconductor layer 121, the active layer 122, and the second conductive semiconductor layer 123 between the first electrode 131 and the second electrode 132.

Accordingly, when the first electrode 131 is heat-treated, at least some regions of the side surface of each of the first conductive semiconductor layer 121, the active layer 122, and the second conductive semiconductor layer 123 may be prevented from being corroded by the first insulating layer 140.

In addition, the first insulating layer 140 may protect each side surface of the semiconductor structure 120 exposed by the recess 128 from oxidation.

In addition, when the first electrode 131 is entirely etched, there is a problem that even the first insulating layer 140 disposed adjacent to the first electrode 131 may be etched. Thus, according to the embodiment, etching is performed only on a partial region of the first electrode 131 and thus an edge region thereof remains, so that the protrusion 131b may be formed. A width d3 of an upper surface of the protrusion 131b may be in a range of 1 μm to 10 μm. When the width d3 is greater than or equal to 1 μm, the first insulating layer 140 may be prevented from being etched. When the width d3 is less than or equal to 10 μm, the area of the first groove is increased to increase a region from which the oxide film is removed, so that a surface area that becomes a resistance may be reduced.

As an example, when the first groove 131a is formed in a partial region of the first electrode 131, a photoresist may be disposed and an exposure process may be performed to place a mask composed of the photoresist. In the mask, a side surface between an upper surface and a lower surface may have an inclination angle with respect to a bottom surface of the substrate. Accordingly, even a partial region of the protrusion 131b of the first electrode 131 may be etched by adjusting the inclination angle of the mask, and thus the thickness of the oxide film OX1 formed on the protrusion 131b may be non-uniformly disposed. In some cases, the oxide film remaining on the side surface and the protrusion 131b of the first electrode 131 may be partially removed.

The first pad 151 may be disposed on the first electrode 131. In this case, the first pad 151 may include a first uneven portion 151a disposed in the first groove 131a. According to such a configuration, an electrical connection between the first pad 151 and the first electrode 131 may be improved so that the operating voltage may be lowered. When the first groove 131a is not formed in the first electrode 131, the oxide film is not removed, thereby increasing a resistance between the first pad 151 and the first electrode 131.

The first pad 151 may cover the side surface of the first electrode 131. Thus, a contact area between the first pad 151 and the first electrode 131 is increased, so that the operating voltage may be further lowered. In addition, since the first pad 151 covers the side surface of the first electrode 131, the first electrode 131 may be protected from moisture or other contaminants penetrating from the outside. Accordingly, the reliability of the semiconductor device may be improved.

The first pad 151 may include a second uneven portion 151b disposed in a separation region d2 between the first insulating layer 140 and the first electrode 131. The second uneven portion 151b may be in direct contact with the first conductive semiconductor layer 121. Thus, an effect of more uniformly spreading a current injected into the first conductive semiconductor layer 121 may be obtained. Here, when the first pad 151 is in direct contact with the first conductive semiconductor layer 121, a resistance between the first pad 151 and the first conductive semiconductor layer 121 may be greater than a resistance between the first electrode 131 and the first conductive semiconductor layer 121. The width of the separation region d2 may be in a range of about 1 μm to 10 μm.

The first pad 151 may have a first region d1 extending on the first insulating layer 140. Accordingly, an entire area of the first pad 151 is increased so that the operating voltage may be lowered.

When the first pad 151 does not extend on the first insulating layer 140, an end of the first insulating layer 140 may be lifted and separated from the first conductive semiconductor layer 121. Accordingly, external moisture and/or other contaminants may be introduced through the gap. As a result, at least some regions of the side surface of each of the first conductive semiconductor layer 121, the active layer 122, and the second conductive semiconductor layer 123 may be corroded or oxidized.

Here, a ratio (d4:d1) of an entire area of a fourth region d4 and an entire area of the first region d1 may be in a range of 1:0.15 to 1:1. The entire area of the first region d1 may be smaller than the entire area of the fourth region d4. Here, the fourth region d4 may be a region in which the first insulating layer 140 is disposed on the first conductive semiconductor layer 121 in a region between the first and second electrodes 131 and 132.

In addition, when the entire area ratio (d4:d1) is greater than or equal to 1:0.15, the area of the first region d1 is increased to cover an upper portion of the first insulating layer 140, so that the first insulating layer 140 may be prevented from being lifted. In addition, since the first insulating layer 140 is disposed between the first electrode 131 and the second electrode 132, the penetration of external moisture or contaminants may be prevented.

Further, when the entire area ratio (d1:d4) is less than or equal to 1:1, an area of the first insulating layer 140 capable of sufficiently covering the region between the first electrode 131 and the second electrode 132 may be secured. Thus, when the first electrode 131 and/or the second electrode 132 are heat-treated, the semiconductor structure may be prevented from being corroded.

According to the embodiment, since the second insulating layer 160 is disposed on the first insulating layer 140 in the region between the first electrode 131 and the second electrode 132, the penetration of external moisture and/or other contaminants may be prevented even when a defect occurs in the first insulating layer 140.

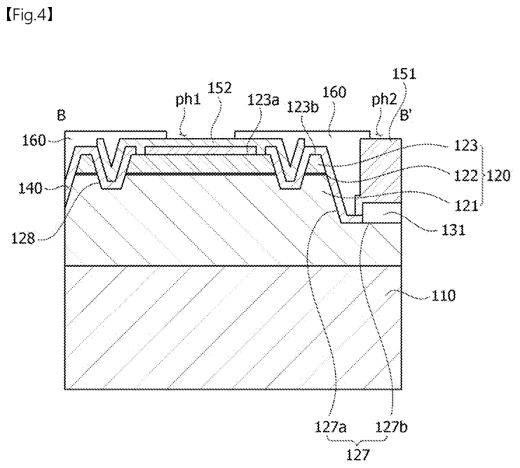

FIG. 4 is a cross-sectional view taken along line BB′ in FIG. 1.

Referring to FIG. 4, as described above, since at least a portion of the second pad 152 is disposed in the recess 128, and the second pad 152 overlaps the second insulating layer 160 in the first direction on the recess 128, it is possible to easily prevent moisture or the like from penetrating into the recess 128. In addition, interfaces exist between a plurality of layers on the recess 128, and thus the propagation of a defect through the interfaces may be sequentially blocked.

Further, the second insulating layer 160 may include a second through hole Ph2 partially disposed on the first pad 151. The second through hole ph2 may be disposed on the first pad 151 to expose a portion of the upper surface of the first pad 151, and the exposed first pad 151 may be electrically connected to the outside through the second through hole ph2.

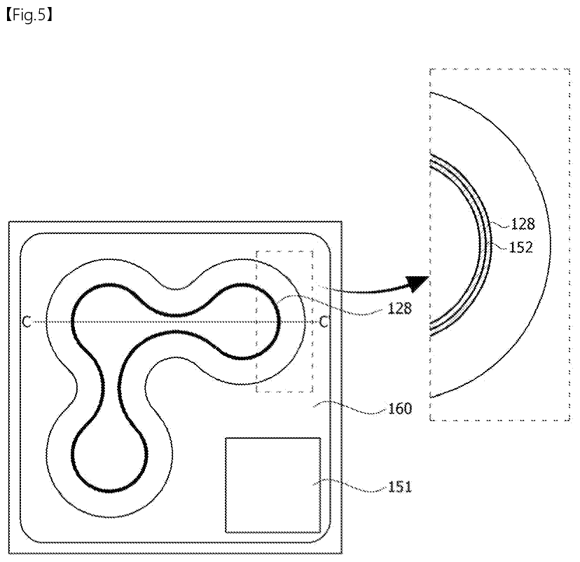

FIG. 5 is a plan view of a semiconductor device according to a second embodiment, and FIG. 6 is a cross-sectional view taken along line CC′ in FIG. 5.

Referring to FIGS. 5 and 6, a semiconductor device 10B according to the second embodiment includes a substrate 210, a semiconductor structure 220 including a first conductive semiconductor layer 221, a second conductive semiconductor layer 223, and an active layer 222 and disposed on the substrate, a first insulating layer 240 partially disposed on the semiconductor structure 220, a first electrode 231 electrically connected to the first conductive semiconductor layer 221, a second electrode 232 electrically connected to the second conductive semiconductor layer 223, a first pad 251 disposed on the first electrode 231, a second pad 252 disposed on the second electrode 232, and a second insulating layer 260 partially covering the first pad 251 and the second pad 252. Further, the semiconductor structure 220 may include a recess 228 and a concave portion 227. As described above, since the concave portion 227 and the recess 228 are disposed to pass through the second conductive semiconductor layer 223 and the active layer 222 and to pass through even a partial region of the first conductive semiconductor layer 221, the first conductive semiconductor layer 221 may be exposed by the concave portion 227 and the recess 228 in some regions.

Further, in the semiconductor device 10B according to the second embodiment, except for the second pad 252 and the second insulating layer 260, the substrate 210, the semiconductor structure 220, the first insulating layer 240, the first electrode 231, the second electrode 232, and the first pad 251 respectively correspond to the elements described above with reference to FIGS. 1 and 2, and thus the contents thereof are applied in the same manner.

Further, as described above, the recess 228 may include a bottom surface 228b located at a lowermost portion thereof, an inner inclined surface 228a disposed inward from the bottom surface 228b, and an outer inclined surface 228c disposed outward from the bottom surface 228b. In addition, the concave portion 227 may include an inclined surface 227a and a bottom surface 227b as described above.

The bottom surface 228b may be located at the lowermost portion of the exposed first conductive semiconductor layer 221 at inner side edges of the active layer 222 or the second conductive semiconductor layer 223. That is, the inner inclined surface 228a may be disposed along a side surface of each of the first conductive semiconductor layer 221, the active layer 222, and the second conductive semiconductor layer 223. In addition, the outer inclined surface 228c may be disposed outward from the bottom surface 228b and may extend from the bottom surface 228b to an upper surface of the second conductive semiconductor layer 223. Also, the outer inclined surface 228c may be disposed along a side surface of each of the first conductive semiconductor layer 221, the active layer 222, and the second conductive semiconductor layer 223. Further, the outer inclined surface 228c and the inner inclined surface 228a may be symmetrically disposed with respect to the bottom surface 228b.

In addition, the second pad 252 may be disposed on the second electrode 232 and may extend on the recess 228. That is, an outer side portion of the second pad 252 may be located on the recess 228. In addition, the second pad 252 may be disposed to be spaced apart from the outermost side of a second upper surface 223b of the second conductive semiconductor layer 223 to have a separation distance d′. With such a configuration, the second pad 252 may not only easily protect the active layer 222 of the active region from external moisture or the like by heat, but also prevent a delamination phenomenon by dissipating heat through the second pad 252.

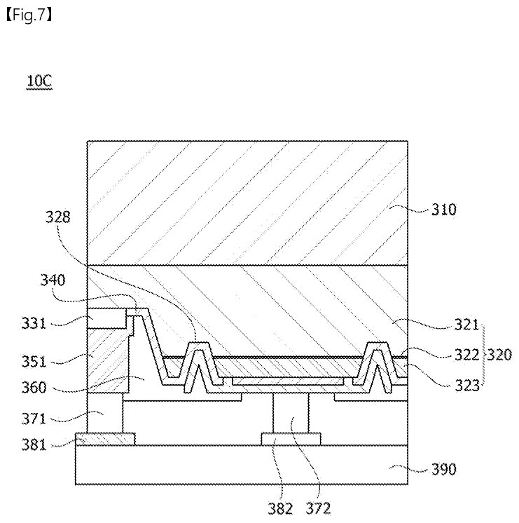

FIG. 7 is a cross-sectional view of a semiconductor device according to a third embodiment.

Referring to FIG. 7, a semiconductor device 10C according to the third embodiment further includes a first bump 371, a plurality of second bumps 372, a first bump 381 and a second bump 382, and a mounting substrate 390.

The bump may include the first bump 371 and the plurality of second bumps 372. The first bump 371 may be disposed on a first pad 351 so as to be electrically connected to the first pad 351. In particular, the first bump 371 may be disposed on the above-described second through hole.

Further, the second bump 372 may be disposed on a second pad 352 so as to be electrically connected to the second pad 352. In addition, the second bump 372 may be disposed on the above-described first through hole, and the second bump 372 may be provided in a plural number. However, the present invention is not limited to such a number.

Similarly, as shown in the drawing, one first bump 371 may be provided, but the embodiment does not limit the number of the first bumps 371.

Further, the plurality of second bumps 372 may include a second-first bump (not shown) and a second-second bump (not shown) that are electrically and spatially separated from each other.

An electrode layer may be disposed between a semiconductor structure 320 and the plurality of bumps. That is, the electrode layer may include a spread layer, but the present invention is not limited to such a configuration.

Further, the first bump 381 and the second bump 382 may each be made of a metal material having electrical conductivity.

In addition, the mounting substrate 390 may be disposed below the first bump 371 and the second bump 372 and may support the first bump 371 and the second bump 372. The mounting substrate 390 may be disposed to face a substrate 310. That is, the mounting substrate 390 may be disposed below the substrate 310. In addition, the mounting substrate 390 may be formed of a semiconductor substrate made of, for example, AlN, BN, SiC, GaN, GaAs, Si, or the like, but is not limited thereto, and may be made of a semiconductor material or insulating material having excellent thermal conductivity. In addition, an element for preventing electrostatic discharge (ESD) in the form of a Zener diode may be included in the mounting substrate 390. As for the elements other than the elements described above, the contents of the elements described in the first embodiment or the second embodiment described above may be applied in the same manner.

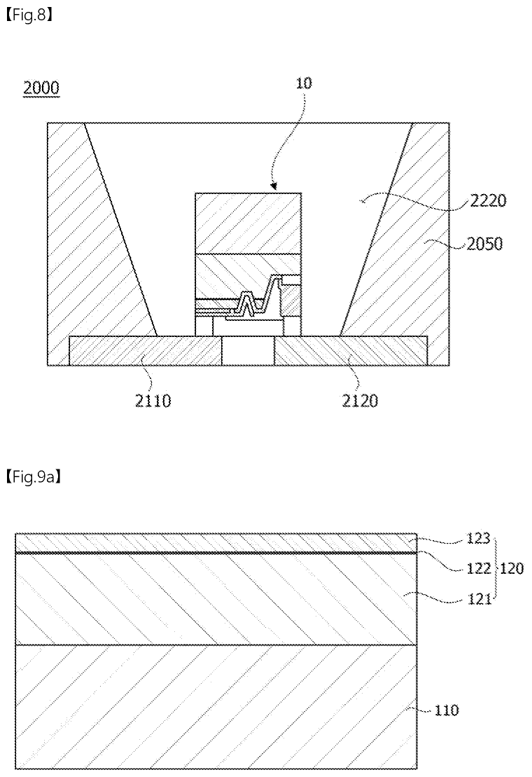

FIG. 8 is a conceptual diagram of a semiconductor device package according to one embodiment.

Referring to FIG. 8, a semiconductor device package 2000 according to one embodiment may include a body 2050, a first electrode layer 2110 and a second electrode layer 2120 installed in the body 2050, a semiconductor device 10 installed in the body 2050 and electrically connected to the first electrode layer 2110 and the second electrode layer 2120, and a molding member 2200 including a phosphor (not shown) and surrounding the semiconductor device 10.

The first electrode layer 2110 and the second electrode layer 2120 are electrically separated from each other and serve to provide power to the semiconductor device 10. In addition, the first electrode layer 2110 and the second electrode layer 2120 may serve to increase light efficiency by reflecting light generated from the semiconductor device 10, and may also serve to discharge heat generated from the semiconductor device 10 to the outside.

The semiconductor device according to the first embodiment is illustrated as the semiconductor device 10, but the present invention is not limited thereto, and a semiconductor device according to embodiments other than those described herein may also be applied as the semiconductor device 10A.

A light-emitting device according to the embodiment may be applied to a backlight unit, a lighting unit, a display apparatus, an indicating apparatus, a lamp, a street light, a vehicle lighting apparatus, a vehicle display apparatus, a smart watch, and the like, but the present invention is not limited thereto.

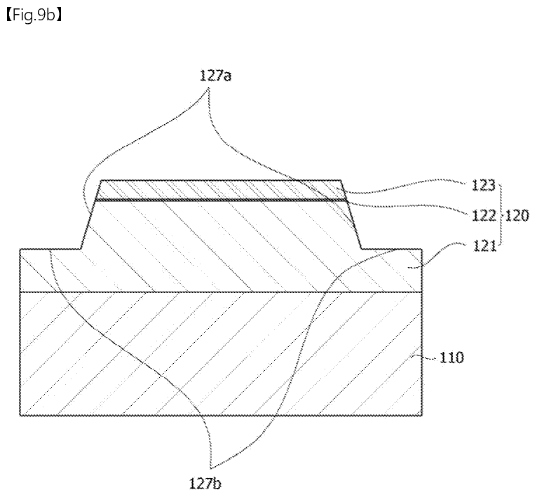

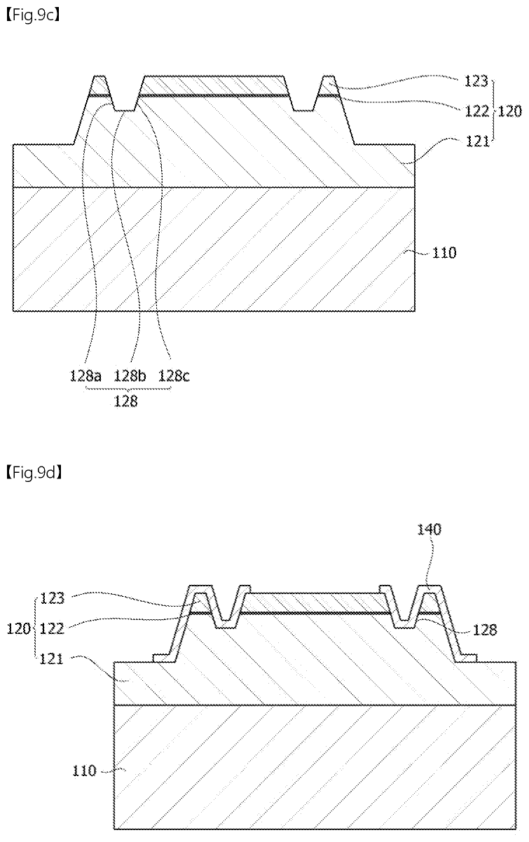

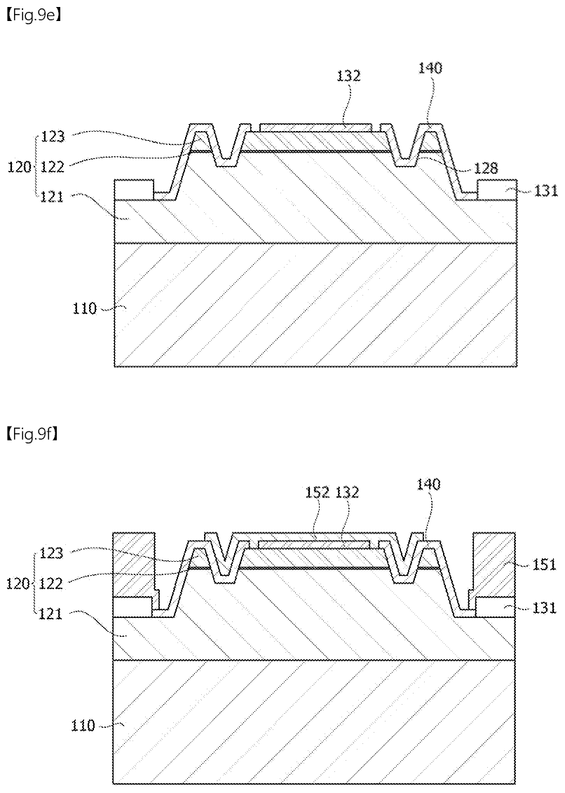

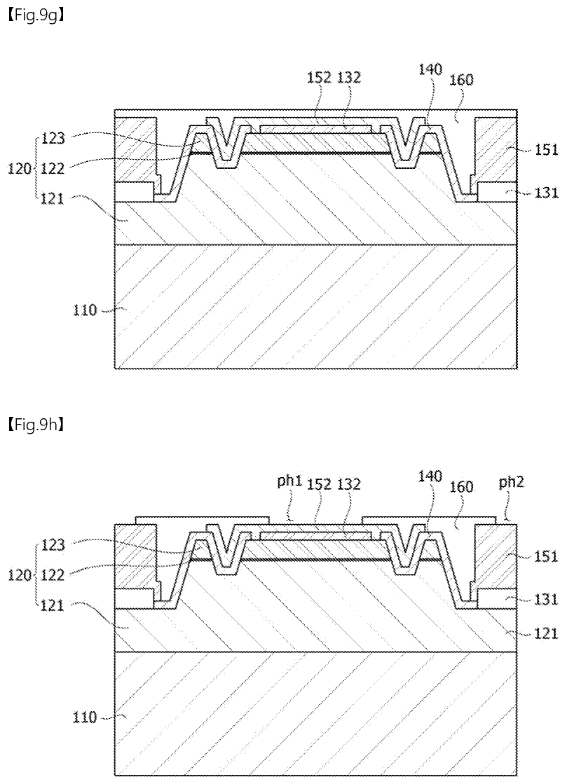

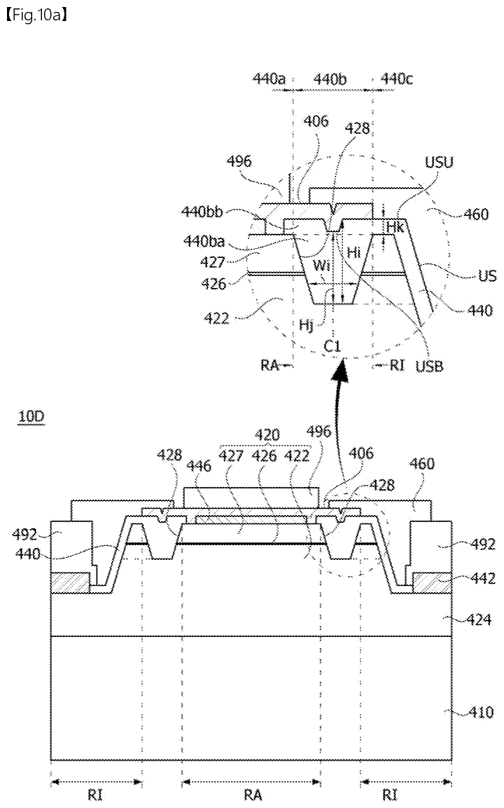

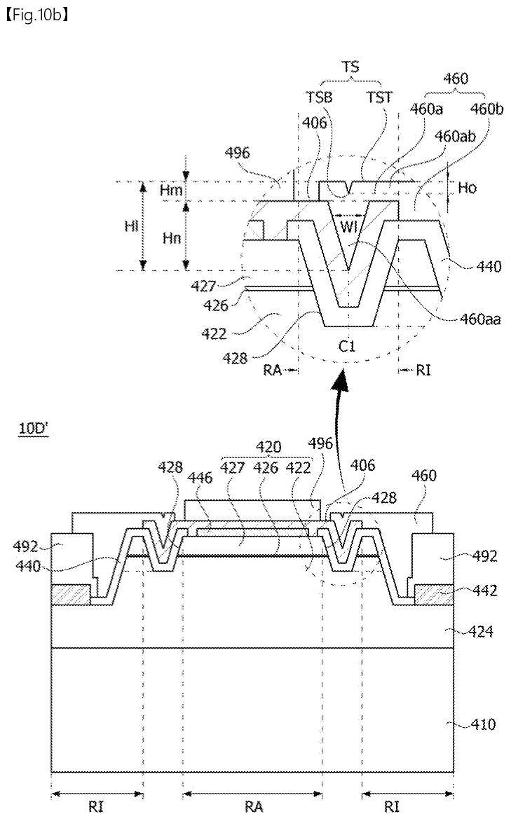

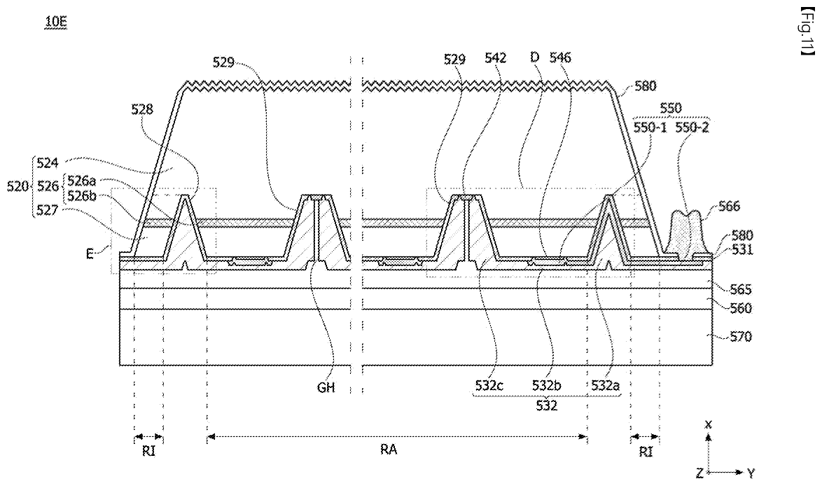

FIGS. 9A to 9H are views illustrating a method of manufacturing the semiconductor device according to the first embodiment.

Referring to FIG. 9A, a substrate 110 may be disposed and a semiconductor structure 120 may be disposed on the substrate 110. The substrate 110 may include a transparent material. For example, the substrate 110 may include one of sapphire (Al₂O₃), SiC, Si, GaN, ZnO, GaP, InP, Ge, and gallium oxide (Ga₂O₃). However, the present invention is not limited such a material.

The semiconductor structure 120 may include a first conductive semiconductor layer 121 disposed on the substrate 110, an active layer 122 disposed on the first conductive semiconductor layer 121, and a second conductive semiconductor layer 123 disposed on the active layer 122. That is, the first conductive semiconductor layer 121, the active layer 122, and the second conductive semiconductor layer 123 may be sequentially stacked on the substrate 110.

The semiconductor structure 120 may be formed using a metal-organic chemical vapor deposition (MOCVD) method, a chemical vapor deposition (CVD) method, a plasma-enhanced chemical vapor deposition (PECVD) method, a molecular-beam epitaxy (MBE) method, a hydride vapor phase epitaxy (HVPE) method, a sputtering method, or the like.

Referring to FIG. 9B, the semiconductor structure 120 may include a concave portion 127 by mesa etching. Accordingly, in the semiconductor structure 120, an inclined surface 127a may be inclined with respect to an upper surface of the second conductive semiconductor layer 123 by etching. In addition, the etching may be wet etching or dry etching, but the present invention is not limited to such a manner. Further, the first conductive semiconductor layer 121 may be exposed by the etching. In addition, a bottom surface 127b extends from the inclined surface 127a, and may be a bottom surface of the exposed portion of the first conductive semiconductor layer 121. Further, the etching may be performed such that the inclined surface 127a and the bottom surface 127b are located at an edge of the semiconductor structure 120.

Referring to FIG. 9C, a recess 128 may be disposed in the semiconductor structure 120. The recess 128 may be formed by mesa etching. In addition, the recess 128 may be formed by wet etching or dry etching, but the present invention is not limited to such a method. The recess 128 and the above-described inclined surface 127a and bottom surface 127b may be formed by the same process, but the present invention is not limited thereto.

Further, the first conductive semiconductor layer 121 may be exposed by the etching. In addition, the recess 128 may extend adjacent to the edge of the semiconductor structure 120 after the above-described mesa etching is performed.

Referring to FIGS. 9D and 9E, a first insulating layer 140 may be disposed on the semiconductor structure 120. After the first insulating layer 140 is disposed, regions in which a first electrode 131 and a second electrode 132, which will be described below, are disposed may be exposed through etching. Afterward, the first electrode 131 and the second electrode 132 may be formed.

That is, the first electrode 131 may be disposed on the first conductive semiconductor layer 121 exposed by the etching, and the first electrode 131 may be electrically connected to the first conductive semiconductor layer 121. The first electrode 131 may be formed using an e-beam evaporation method, a thermal evaporation method, an MOCVD method, a sputtering method, and a PLD method, but the present invention is not limited thereto.

In addition, the second electrode 132 may be disposed on the second conductive semiconductor layer 123 and may be electrically connected to the second conductive semiconductor layer 123. Similarly, the second electrode 132 may be formed using an e-beam evaporation method, a thermal evaporation method, an MOCVD method, a sputtering method, and a PLD method, but the present invention is not limited thereto. However, the formation order of the first insulating layer 140, the first electrode 131, and the second electrode 132 may be changed. Further, the first and second electrodes 131 and 132 may be formed by the same process, but the present invention is not limited thereto, and the arrangement of the first and second electrodes 131 and 132 may be variously changed.

Referring to FIG. 9F, a first pad 151 may be disposed on the first electrode 131. A portion of the first pad 151 may be disposed on the first insulating layer 140. The first pad 151 may be electrically connected to the first electrode 131 to form an electrical path with the first electrode 131 and the first conductive semiconductor layer 121.

In addition, the second pad 152 may be disposed on the second electrode 132 such that at least a portion of the second pad 152 is disposed in the recess 128, and may cover the second electrode 132. Further, the second pad 152 may be disposed on a partial region of the first insulating layer 140. Further, the second pad 152 may be electrically connected to the second electrode 132 to form an electrical path with the second electrode 132 and the second conductive semiconductor layer 123.

Referring to FIG. 9G, a second insulating layer 160 may be disposed on the first insulating layer 140, the first pad 151, and the second pad 152. In particular, a second through hole ph2 may be formed by etching to expose a portion of a connection electrode 135 of the second insulating layer 160. Further, the second insulating layer 160 may be disposed on some regions of the first pad 151 and the second pad 152, so that the first pad 151 and the second pad 152 may be partially exposed. In addition, as shown in FIG. 7, first and second bumps, a mounting substrate, and the like may be additionally disposed on the exposed portions. Further, a dicing process may be performed to manufacture a plurality of semiconductor devices after the first pad 151 and the second pad 152 are disposed.

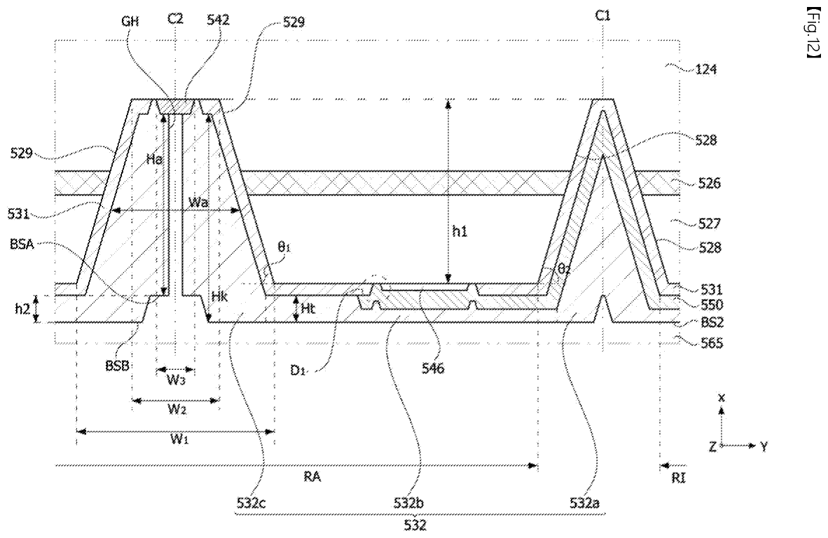

FIG. 10A is a cross-sectional view of a semiconductor device according to a fourth embodiment, and FIG. 10B is a view illustrating a modified example of FIG. 10A.

First, referring to FIG. 10A, a semiconductor device 10D according to the fourth embodiment may include a semiconductor structure 420 including a first conductive semiconductor layer 424, a second conductive semiconductor layer 427, and an active layer 426, a first electrode 442 electrically connected to the first conductive semiconductor layer 424, and a second electrode 446 electrically connected to the second conductive semiconductor layer 427.

As described above, the semiconductor structure 420 may include the first conductive semiconductor layer 424, the active layer 426, and the second conductive semiconductor layer 427, and may include a first recess 428 that passes through the second conductive semiconductor layer 427 and the active layer 426, and exposes a partial region of the first conductive semiconductor layer 424. In addition, as for the contents of the first electrode 442, the second electrode 446, and a first insulating layer 440, the corresponding contents described above may be equally applied. Here, the first insulating layer 440 refers to the first insulating layer 140 in FIG. 1.

In addition, as described above, the first recess 428 may be disposed along an outer side surface of the semiconductor structure 420 to separate the semiconductor structure 420 into a second region RI and a first region RA. As illustrated in FIG. 1, the first recess 428 may form a closed loop in a plan view. However, the present invention is not limited to the above.

In addition, the first region RA may be located on an inner side of the closed loop, and the second region RI may be located on an outer side of the closed loop. However, as described above, the first recess 428 may be divided into the second region RI and the first region RA by an imaginary line formed by extending the first recess 428 along an edge of the semiconductor structure 420, but in the following, descriptions will be given on the basis of the case in which the first recess 428 forms a closed loop. Further, the contents of the second region RI may be applied in the same manner as described with reference to FIG. 1.

In the present embodiment, when the first insulating layer 440 or a second insulating layer 460 is delaminated, since the active layer 426 of the second region RI is located outside the semiconductor structure 420, the active layer 426 may be oxidized by external moisture and contaminants. However, the oxidation generated in the active layer 426 of the second region RI may be prevented from spreading to the active layer 426 of the first region RA by the first recess 428.

Further, within the first recess 428, the first insulating layer 440 may increase in height toward an edge of the first recess 428 with respect to a center of the first recess 428. With such a configuration, even when first and second pads 492 and 496 to be described below are partially disposed, the occurrence of an inclination or height difference due to the first recess 428 may be prevented, so that it is possible to easily prevent occurrence of delamination or the like due to voids caused by the height difference.

In addition, the first pad 492 may be disposed on the first electrode 442. Further, the second pad 496 may be disposed on the second electrode 446. In addition, a thickness of each of the first pad 492 and the second pad 496 may be adjusted so that an upper surface of the first pad 492 and an upper surface of the second pad 496 may be disposed to be coplanar with each other with respect to a lower surface of the semiconductor device 10D. For example, when the first electrode 442 and the second electrode 446 are bonded after minimizing the height difference between an upper surface of the first electrode 442 and an upper surface of the second electrode 446, the generation of voids may be suppressed.

Further, even in a flip-chip type semiconductor device, it is possible to easily prevent the active layer 426 of the second region RI from being oxidized by external moisture and contaminants by the first recess 428.

In an embodiment, the first insulating layer 440 may include a first-first insulating layer 440a located inward from the first recess 428, a first-second insulating layer 440b overlapping the first recess 428 in a stacking direction of the semiconductor structure, and a first-third insulating layer 440c disposed outward from the first recess 428. In addition, the first-second insulating layer 440b may include a (1-2a)th insulating layer 440ba overlapping the first recess 428 in a direction perpendicular to the stacking direction, and a (1-2b) insulating layer 440bb located above the (1-2a)th insulating layer 440ba. In addition, the first insulating layer 440 may have an upper surface US, and the upper surface US may include a first upper surface USU positioned at the top and a first lower surface USB.

Here, a width wi of the (1-2a)th insulating layer 440ba may increase toward the (1-2b) insulating layer 440bb. Further, a thickness Hj of the (1-2a)th insulating layer 440ba may increase toward an edge of the first recess 428 from a central portion of the first recess 428.

Further, the maximum thickness Hj of the (1-2a)th insulating layer 440ba may be less than a maximum thickness Hi of the first-second insulating layer 440b at a central portion C1 of the first recess 428. In addition, the maximum thickness Hi of the first-second insulating layer 440b may be greater than a height of the first recess 428. That is, the height of the first recess 428 may be less than a length between the first upper surface USU and a lower surface of the first-second insulating layer 440b.

In addition, the thickness of the first-second insulating layer 440b at the central portion C1 of the first recess 428 may be greater than the thickness of the first-second insulating layer 440b outside the first recess 428.

Further, the thickness of the first recess 428 may have a value between the thickness Hj of the first insulating layer 440 at the central portion C1 of the first recess 428 and the maximum thickness Hi of the first insulating layer 440 within the first recess 428.

With such a configuration, a height difference may be reduced at the interface between the first insulating layer 440, and the second electrode or the second pad on the first insulating layer 440. In other words, each of the second electrode and the second pad is flat so that voids generated at the interface of each layer below the first insulating layer may be suppressed. Further, the interface of the second insulating layer 460 may also be flat. Accordingly, by suppressing the voids, bonding, thermal resistance, and the like at the interface may be improved, so that the reliability of the semiconductor device may be improved.

Further. as for elements other than the elements described with reference to the present drawing, the contents of the elements in the embodiments described above, for example, the substrate, the semiconductor structure including the first conductive semiconductor layer, the second conductive semiconductor layer, and the active layer and disposed on the substrate, the first insulating layer, the first electrode, the second electrode, the first pad, the second pad, and the second insulating layer, may be applied in the same manner.

Referring to FIG. 10B, in a semiconductor device according to the modified example, a minimum thickness of the second insulating layer 460 may be less than a maximum thickness thereof within the first recess 428. That is, as in FIG. 17 to be described later, the thickness of the second insulating layer 460 is formed to be greater than that in the first recess 428, and thus the height difference of the second insulating layer 460, which may be generated due to the first recess 428, within the first recess 428 may be reduced.

More specifically, the second insulating layer 460 may include a second-first insulating layer 460a overlapping the first recess 428 in the above-described stacking direction, and a second-second insulating layer 460b located outward from the first recess 428.

Further, the second-first insulating layer 460a may include a (2-1a)th insulating layer 460aa overlapping the first recess 428 in a direction perpendicular to the stacking direction, and a (2-1b) insulating layer 460ab located above the (2-1a)th insulating layer 460aa.

In addition, the second insulating layer 460 may have an upper surface TS, and the upper surface TS may include a first upper surface TST located at an uppermost portion of the upper surface TS and a first lower surface TSB located at a lowermost portion of the upper surface TS.

In the present embodiment, a height Hn of the (2-1a)th insulating layer 460aa may be decreased toward the edge of the first recess 428 at the central portion C1 of the first recess 428.

Further, in contrast, a width W1 of the (2-1a)th insulating layer 460aa may increase toward the (2-1b) insulating layer 460ab on the basis of the central portion C1 of the first recess 428. With such a configuration, in the upper surface of the second-first insulating layer 460a, a height difference between the surface located at the uppermost portion and the surface located at the lowermost portion may be reduced.

In other words, a height difference Ho between the first upper surface TST and the first lower surface TSB of the second-first insulating layer 460a may be reduced. With such a configuration, the upper surface of the second insulating layer 460 may be flat, and thus when the upper surface of the second insulating layer 460 is adhered to other members, the adhesion therebetween may be improved, thereby improving the reliability of the semiconductor device.

Further, in the second-first insulating layer 460a, a height difference between a height h1 between the first upper surface TST and a lowermost surface and the height Hn between the first lower surface TSB and the lowermost surface may be less than a minimum height Hm of the second-first insulating layer 460a.

With the above-described configuration, in the semiconductor device according to the embodiment, the generation of voids may be suppressed, so that reliability may be improved.

Further, the above description may be equally applied not only to the flip-type semiconductor device having the first recess 428 but also to a vertical-type semiconductor device to be described below with reference to FIGS. 11 to 17.

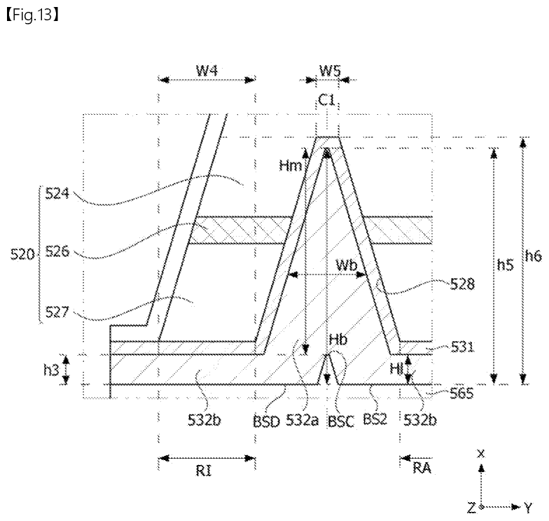

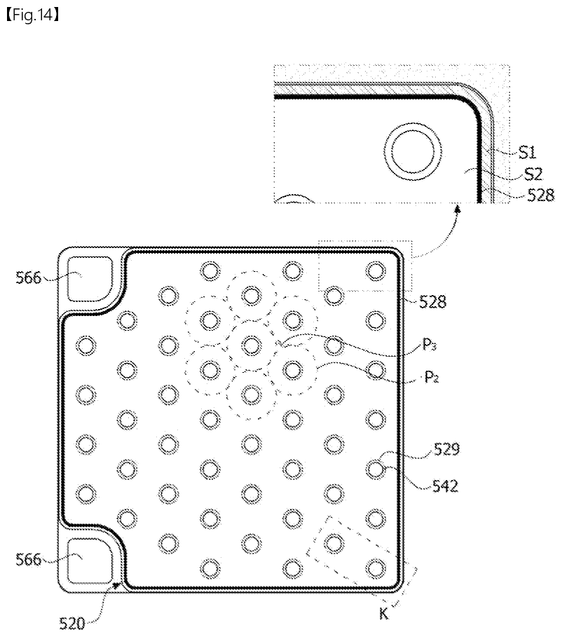

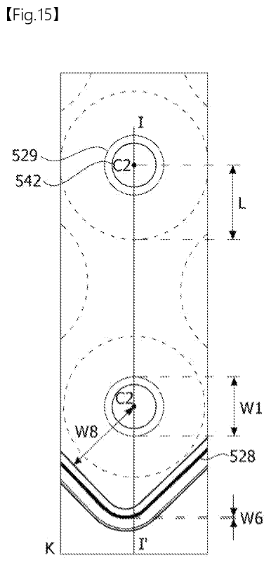

FIG. 11 is a conceptual diagram of a semiconductor device according to a fifth embodiment, FIG. 12 is an enlarged view of portion D in FIG. 11, and FIG. 13 is an enlarged view of portion E in FIG. 11.

Referring to FIG. 11, a semiconductor device 10E according to the fifth embodiment may include a semiconductor structure 520 including a first conductive semiconductor layer 524, a second conductive semiconductor layer 527, and an active layer 526, a first insulating layer 531 partially disposed on a lower portion of the semiconductor structure 520, a first electrode 542 electrically connected to the first conductive semiconductor layer 524, a second electrode 546 electrically connected to the second conductive semiconductor layer 527, a first conductive layer 550 electrically connected to the second electrode 546 and disposed below the first insulating layer 531, a second insulating layer 532 disposed below the first conductive layer 550, a second conductive layer 565 disposed below the second insulating layer 532, a bonding layer 560 disposed below the second conductive layer 565, and a substrate 570 disposed below the bonding layer 560.

First, the semiconductor structure 520 may include the first conductive semiconductor layer 524, the active layer 526, and the second conductive semiconductor layer 527. In this case, the first conductive semiconductor layer 524, the active layer 526, and the second conductive semiconductor layer 527 may be disposed in a first direction (X-axis direction). Hereinafter, the first direction (X-axis direction), which is a thickness direction of each layer, will be defined as a vertical direction, and a second direction (Y-axis direction) perpendicular to the first direction (X-axis direction) will be defined as a horizontal direction. In addition, a third direction (Z-axis direction) is a direction perpendicular to both the first direction (X-axis direction) and the second direction (Y-axis direction).

The first conductive semiconductor layer 524 may be implemented with a III-V group or II-VI group compound semiconductor and may be doped with a first dopant. The first conductive semiconductor layer 524 may be made of semiconductor materials having a composition formula of Inₓ₁Al_{y1}Ga_{1-x1-y1}N (0<=x1<=1, 0<=y1<=1, and 0<=x1+y1<=1), for example, semiconductor materials selected from among GaN, AlGaN, InGaN, InAlGaN, and the like. In addition, the first dopant may be an n-type dopant such as Si, Ge, Sn, Se, or Te. When the first dopant is an n-type dopant, the first conductive semiconductor layer 524 doped with the first dopant may be an n-type semiconductor layer.

The active layer 526 may be disposed between the first conductive semiconductor layer 524 and the second conductive semiconductor layer 527. The active layer 526 may be a layer at which electrons (or holes) injected through the first conductive semiconductor layer 524 and holes (or electrons) injected through the second conductive semiconductor layer 527 are recombined. In the active layer 526, as the electrons and the holes are recombined, the electrons may transition to a lower energy level and light having a wavelength corresponding to band gap energy of a well layer included in the active layer 526, which will be described below, may be generated. Light of a wavelength having the highest intensity relative to other wavelengths, among wavelengths of light emitted from the semiconductor device, may be ultraviolet rays, and the ultraviolet rays may be near ultraviolet rays, far ultraviolet rays, or deep ultraviolet rays described above.

The active layer 526 may have one structure among a single well structure, a multi-well structure, a single quantum well structure, an MQW structure, a quantum dot structure, and a quantum wire structure, but the structure of the active layer 526 is not limited thereto.

The second conductive semiconductor layer 527 may be formed on the active layer 526 and implemented with a III-V group or II-VI group compound semiconductor, and the second conductive semiconductor layer 527 may be doped with a second dopant. The second conductive semiconductor layer 527 may be made of semiconductor materials having a composition formula Inₓ₅Al_{y2}Ga_{1-x5-y2}N (0<=x5<=1, 0<=y2<=1, and 0<=x5+y2<=1) or materials selected from among AlInN, AlGaAs, GaP, GaAs, GaAsP, and AlGaInP. When the second dopant is a p-type dopant such as Mg, Zn, Ca, Sr, Ba, or the like, the second conductive semiconductor layer 527 doped with the second dopant may be a p-type semiconductor layer.

Additionally, an electron blocking layer (not shown) may be disposed between the active layer 526 and the second conductive semiconductor layer 527. The electron blocking layer (not shown) may block electrons, which are supplied from the first conductive semiconductor layer 524 to the active layer 526, from flowing out to the second conductive semiconductor layer 527 without being recombined in the active layer 526 to emit light, and thus the recombination probability of electrons and holes in the active layer 526 may be increased. An energy band gap of the electron blocking layer (not shown) may be greater than an energy band gap of the active layer 526 and/or the second conductive semiconductor layer 527.

The electron blocking layer (not shown) may be selected from semiconductor materials having a composition formula of Inₓ₁Al_{y1}Ga_{1-x1-y1}N (0<=x1<=1, 0<=y1<=1, and 0<=x1+y1<=1), for example, semiconductor materials selected from among AlGaN, InGaN, InAlGaN, and the like, but the present invention is not limited thereto. In the electron blocking layer (not shown), a first layer (not shown) having a high Al composition and a second layer (not shown) having a low Al composition may be alternately disposed.

In addition, the first conductive semiconductor layer 524, the active layer 526, and the second conductive semiconductor layer 527 may all include aluminum. Accordingly, the first conductive semiconductor layer 524, the active layer 526, and the second conductive semiconductor layer 527 may each be made of AlGaN. However, the present invention is not necessarily limited thereto.

Further, when the first conductive semiconductor layer 524, the active layer 526, and the second conductive semiconductor layer 527 all include Al, the electron blocking layer (not shown) may have an Al composition of 50% to 90%. When the Al composition of the electron blocking layer (not shown) is less than 50%, a height of an energy barrier for blocking electrons may be insufficient, and light emitted from the active layer 526 may be absorbed by the electron blocking layer (not shown). When the Al composition of the electron blocking layer (not shown) exceeds 90%, electrical characteristics of the semiconductor device may be degraded.

In addition, the semiconductor structure 520 may include a first recess 528 and a second recess 529. Hereinafter, the case in which the semiconductor structure 520 includes both the first recess 528 and the second recess 529 is illustrated, but the semiconductor structure 520 may include at least one of the first recess 528 and the second recess 529.

The first recess 528 may be disposed to pass through the second conductive semiconductor layer 527 and the active layer 526 and to pass through even a partial region of the first conductive semiconductor layer 524. Accordingly, the partial region of the first conductive semiconductor layer 524 may be exposed by the first recess 528.

In addition, the first recess 528 may be disposed to extend along an edge of the semiconductor structure 520. Further, the first recess 528 may be disposed continuously or discontinuously. For example, when the first recess 528 is continuously disposed, the first recess 528 may be in the form of a closed loop on a plane (ZY plane) in the semiconductor structure 520. Hereinafter, descriptions will be given on the basis of the case in which first recess 528 is in the form of a closed loop.

Accordingly, the semiconductor structure 520 may be divided into a first region RA and a second region RI by the first recess 528. Here, the first region RA may be located inward from the first recess 528 in the semiconductor structure 520, and the second region RI may be located outward from the first recess 528 in the semiconductor structure 520 (Although the first recess 528 has been described with reference to the case in which the first recess 528 is in the form of a closed loop as described above, the contents of the first region and the second region may be equally applied even when the first recess 528 is discontinuously disposed. However, in this case, the first region and the second region are partitioned by an imaginary line connected by extending the first recess 528 along the edge of the semiconductor structure 520).

Accordingly, an active layer 526a of the first region RA and an active layer 526b of the second region RI may be disposed to be spaced apart from each other. In addition, the first region RA may be an emission region in which the active layer 526 located therein is disposed adjacent to the second recess 529 and thus electrons and holes are combined. In contrast, the second region RI may be a non-emission region in which the active layer 526 located therein is spaced apart from the active layer 526a of the first region RA, and is disposed closer to an edge of the semiconductor structure 520 than the second recess 529 and thus the combination of electrons and holes does not occur.

With such a configuration, even when a passivation layer 580 surrounding side and upper surfaces of the semiconductor structure 520 is delaminated or cracked due to heat, which is generated due to light emission of the semiconductor device, external high temperature and high humidity environment, a difference in thermal expansion coefficient between the semiconductor structures 520, and the like, moisture, contaminants, or the like penetrating into the semiconductor structure 520 from the outside may be prevented from oxidizing the active layer 526a of the first region RA, which is an emission region.

Specifically, in the semiconductor device, the first recess 528 may prevent a direct connection between the active layer 526a of the first region RA and the active layer 526b of the second region RI. Accordingly, when the active layer 526b of the second region RI adjacent to a sidewall of the semiconductor structure 520 is exposed to the outside due to the above-described delamination, the active layer 526b of the second region RI may be oxidized. However, since the active layer 526a of the first region RA and the active layer 526b of the second region RI are spaced apart from each other due to the separation by the first recess 528, even when the active layer 526b of the second region RI is oxidized, the active layer 526a of the first region RA may be protected from the oxidation. That is, the first recess 528 may protect the oxidation of the active layer 526b of the emission region from external moisture.

In particular, in a case in which the semiconductor device generates ultraviolet light, an energy band gap and an Al concentration of the active layer 526 increase compared to a case in which the semiconductor device generates visible light, and thus the semiconductor device may be more vulnerable to oxidation. Accordingly, when the semiconductor device described herein generates ultraviolet light, reliability may be greatly improved.

Further, when the semiconductor structure 520 generates ultraviolet light, the semiconductor structure 520 has high band gap energy, and thus, in the semiconductor structure 520, current spreading characteristics may be degraded and an effective light-emitting region may be reduced in size.

For example, when the semiconductor structure 520 includes a GaN-based compound semiconductor, in order to emit ultraviolet light, the semiconductor structure may include AlₓGa₍₅₋ₓ₎N (0<=x<=1) containing a large amount of Al. Here, as the value of x indicating the Al content increases, the resistance of the semiconductor structure 520 may increase, and the current spreading and current injection characteristics of the semiconductor structure 520 may be degraded.

Accordingly, current spreading in the semiconductor structure 520 may be carried out in the first region RA. As a result, the semiconductor device 10E described herein may maintain light output even when the first recess 528 is included. In addition, as described above, due to the first recess 528, the region in which the oxidation is carried out by moisture or the like is limited to an outward region (e.g., the first region RA) of the first recess 528, so that the active layer 526a located in an effective light-emitting region (e.g., the second region RI) may be protected from oxidation, thereby maintaining the light output.

Further, the first recess 528 and the second recess 529 may each have a center. Further, when the first recess 528 and the second recess 529 may each have a circular shape, the center may be the center of the circular shape. However, the present invention is not limited to such a shape. Also, the center of the second recess 529 may be the same as the center of the first electrode 542 inside the second recess 529. In addition, such a description is applied to all embodiments of the present specification.

Further, a ratio of an area of the upper surface of the semiconductor structure 520 and an area of a lower surface of the first recess 528 may be in a range of 1:0.01 to 1:0.03.

When the ratio of the area of the upper surface of the semiconductor structure 520 and the area of the lower surface of the first recess 528 is less than 1:0.01, there is a limitation in preventing oxidation of the active layer 526 by contaminants. In addition, when the ratio of the area of the upper surface of the semiconductor structure 520 and the area of the lower surface of the first recess 528 is greater than 1:0.03, there is a limitation that light efficiency is reduced.

The second recess 529 may be disposed to pass through the second conductive semiconductor layer 527 and the active layer 526 and to pass through even a partial region of the first conductive semiconductor layer 524. Accordingly, the partial region of the first conductive semiconductor layer 524 may be exposed by the second recess 529. In addition, the second recess 529 may be disposed further inward than the first recess 528 in the semiconductor structure 520. For example, when the first recess 528 is continuously disposed, the second recess 529 may be surrounded by the first recess 528 on a plane (ZY plane).

Further, the second recess 529 may be disposed in the first region RA, in other word, the second recess 529 may overlap the first region RA in the vertical direction (X-axis direction).

The first electrode 542 may be disposed in the second recess 529 and electrically connected to the first conductive semiconductor layer 524.

In addition, the first electrode 542 may be disposed on a low concentration layer of the active layer 526 to secure relatively smooth current injection characteristics. That is, the second recess 529 may be formed to extend to a region of the low concentration layer of the first conductive semiconductor layer 524. This is because a high concentration layer of the first conductive semiconductor layer 524 has a high Al concentration and thus has relatively low current spreading characteristics.

Further, the first electrode 542 is disposed inward from the first recess 528, and thus may overlap the first region RA in the vertical direction (X-axis direction). In addition, when a current is injected through the first electrode 542, the semiconductor structure 520 may generate light.

The second electrode 546 may be disposed below the second conductive semiconductor layer 527 and electrically connected to the second conductive semiconductor layer 527. Further, the second electrode 546 is disposed inward from the first recess 528, and thus may overlap the first region RA in the vertical direction (X-axis direction).

The first electrode 542 and the second electrode 546 may be ohmic electrodes. The first electrode 542 and the second electrode 546 may each include at least one among ITO, IZO, IZTO, IAZO, IGZO, IGTO, AZO, ATO, GZO, IZON, AGZO, IGZO, ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf, but the present invention is not limited to the above materials. As an example, the first electrode 542 may include a plurality of metal layers (e.g., Cr/Al/Ni), and the second electrode 546 may be ITO.

The first insulating layer 531 may be disposed below the semiconductor structure 520 and may insulate the first electrode 542 from the active layer 526 and the second conductive semiconductor layer 527. Further, the first insulating layer 531 may electrically insulate the second electrode 546 and the first conductive layer 550 from the second conductive layer 565.

In addition, the first insulating layer 531 may be disposed below the semiconductor structure 520 except for regions in which the first electrode 542 and the second electrode 546 are disposed. As a result, external moisture or the like may be prevented from penetrating into the semiconductor structure 520 from an edge of the semiconductor structure 520 during the process of the semiconductor structure 10E.

Further, the first insulating layer 531 may be disposed in the first recess 528 to maintain insulation between the active layer 526a of the first region RA and the active layer 526b of the second region RI.

The first insulating layer 531 may be made of at least one material selected from the group consisting of SiO₂, SiₓO_{y}, Si₃N₄, SiₓN_{y}, SiOₓN_{y}, Al₂O₃, TiO₂, AlN, and the like, but the present invention is not limited thereto. The first insulating layer 531 may be formed as a single-layer or a multi-layer. As an example, the first insulating layer 531 may be a DBR having a multi-layer structure including a Si oxide or a Ti compound. However, the present invention is not necessarily limited thereto, and the first insulating layer 531 may include various reflection structures.

Further, when the first insulating layer 531 performs a reflection function, the first insulating layer 531 may upward reflect light that is laterally emitted from the active layer 526, thereby enhancing light extraction efficiency. In this case, as the number of second recesses 529 increases, light extraction efficiency may further increase.

The first conductive layer 550 may be disposed below the second electrode 546 and may cover the second electrode 546. In addition, the first conductive layer 550 may extend to the outside of the semiconductor device 10E, and an electrode pad 566, the first conductive layer 550, and the second electrode 546 may form one electrical channel.

Further, the first conductive layer 550 may be disposed below the first insulating layer 531 so as to be in contact with the first insulating layer 531. In addition, the first conductive layer 550 may be made of a material having high adhesion with the first insulating layer 531 and may be made, for example, of at least one material selected from the group consisting of materials such as Cr, Ti, Ni, and Au, or an alloy thereof, and may be formed of a single-layer or a plurality of layers.

Further, the first conductive layer 550 may be disposed between the first insulating layer 531 and the second insulating layer 532 to be described below. Accordingly, the first conductive layer 550 may be protected from the penetration of external moisture or contaminants by the first insulating layer 531 and the second insulating layer 532.

Further, the first conductive layer 550 may be disposed inside the semiconductor device 10E such that the first conductive layer 550 is not exposed at the edge of the semiconductor device 10E. In addition, the first conductive layer 550 may be partially disposed between the first insulating layer 531 and the second electrode 546.

Further, the first conductive layer 550 may include a first conductive region 550-1 and a second conductive region 550-2. First, the first conductive region 550-1 may be a region disposed inward from the first recess 528, and the second conductive region 550-2 may be a region extending from the first conductive region 550-1 toward the electrode pad 566.

In addition, the first conductive layer 550 may be disposed such that most thereof is surrounded by the first recess 528, but a portion of the first conductive layer 550, which is adjacent to the electrode pad 566, may be disposed to extend to the electrode pad 566 disposed outside the semiconductor structure 520. That is, the first conductive region 550-1 may be surrounded by the first recess 528, and the second conductive region 550-2 may extend from the first conductive region 550-1 to the electrode pad 566 disposed outside the semiconductor structure 520.

A reflective layer (not shown) may be disposed on the first conductive layer 550. In addition, the reflective layer (not shown) may be disposed between the second electrode 546 and the first conductive layer 550, and specifically, may be disposed below the second electrode 546.

Further, the reflective layer (not shown) may electrically connect the second electrode 546 and the first conductive layer 550. Thus, when the reflective layer (not shown) is present, the electrode pad 566, the first conductive layer 550, the reflective layer (not shown), and the second electrode 546 may form one electrical channel.

Further, the reflective layer (not shown) may be made of a material having high reflectivity, and may include one of Ag and Rh, but the present invention is not limited to such a material.

The second insulating layer 532 may be disposed below the first conductive layer 550, the first insulating layer 531, the semiconductor structure 520, and the first electrode 542.

Further, a second-third insulating layer 532c of the second insulating layer 532 may include a through hole GH, and the second conductive layer 565 may be electrically connected to the first electrode 542 through the through hole GH. Thus, the second insulating layer 532 may insulate the second electrode 546 and the first conductive layer 550 from the second conductive layer 565.

Further, the second insulating layer 532 and the first insulating layer 531 may be made of the same material or may be made of different materials. In addition, since the separate second insulating layer 532 is disposed on the first insulating layer 531, defects formed in the first insulating layer 531 may be difficult to propagate to the second insulating layer 532, so that the second insulating layer 532 may serve to shield the propagation of the defects at the interface between the first insulating layer 531 and the second insulating layer 532.

Further, the second insulating layer 532 may include a second-first insulating layer 532a disposed at a position corresponding to the first recess 528, the second-third insulating layer 532c disposed at a position corresponding to the second recess 529, and a second-second insulating layer 532b other than the second-first insulating layer 532a and the second-third insulating layer 532c. That is, the second-second insulating layer 532b may correspond to the outside of each of the first recess 528 and the second recess 529. In other words, the second-first insulating layer 532a overlaps the first recess 528 in the vertical direction (X-axis direction) in the second insulating layer 532, and the second-second insulating layer 532b does not overlap the first recess 528 and the second recess 529 in the vertical direction (X-axis direction), and the second-third insulating layer 532c overlaps the second recess 529 in the vertical direction (X-axis direction).

In addition, an entire width of the second-first insulating layer 532a may increase toward an edge of the first recess 528 on the basis of a central portion of the first recess 528. Further, an entire width of the second-third insulating layer 532c may increase toward an edge of the second recess 529 on the basis of a central portion of the second recess 529. In addition, a thickness (interchanged with a height) of each of the second-first insulating layer 532a and the second-third insulating layer 532c may be less than a height h1 of each of the first recess 528 and the second recess 529, and may be greater than a thickness of the first-second insulating layer 532c. The second insulating layer 532 will be described in detail below with reference to FIGS. 12 and 13.

The second conductive layer 565 may be disposed below the second insulating layer 532 and the first electrode 542. In addition, the second conductive layer 565 may be disposed in the through hole GH of the second-third insulating layer 532c and electrically connected to the first electrode 542. According to the embodiment, since the second insulating layer 532 is disposed below the first insulating layer 531 in a region between the first electrode 542 and the second electrode 546, even when a defect occurs in the second insulating layer 532, the first insulating layer 531 may prevent external moisture and/or other contaminants from penetrating.

In addition, the second conductive layer 565 may be made of a material having high reflectivity. As an example, the second conductive layer 565 may include a metal such as Ti, Ni, or the like.

The bonding layer 560 may be disposed below the semiconductor structure 520. However, the second conductive layer 565 may not exist below the semiconductor structure 520 in the absence of the second recess 529. In addition, the position of the bonding layer 560 may be changed according to the structure of the semiconductor device 10E.

The bonding layer 560 may bond the substrate 570 and the second conductive layer 565, which will be described below.

Further, the bonding layer 560 may include a conductive material. As an example, the bonding layer 560 may include a material selected from the group consisting of gold, tin, indium, aluminum, silicon, silver, nickel, and copper, or an alloy thereof.

The substrate 570 may be made of a conductive material. As an example, the substrate 570 may include a metal or a semiconductor material. The substrate 570 may include a metal having high electrical conductivity and/or thermal conductivity. In this case, heat generated during an operation of the semiconductor device 10E may be rapidly discharged to the outside. In addition, when the substrate 570 is made of a conductive material, the first electrode 542 may be supplied with a current from the outside through the substrate 570.

The substrate 570 may include a material selected from the group consisting of silicon, molybdenum, tungsten, copper, and aluminum or an alloy thereof.

The passivation layer 580 may be disposed on upper and side surfaces of the semiconductor structure 520. A thickness of the passivation layer 580 may be in a range of 200 nm to 500 nm. When the thickness is greater than or equal to 200 nm, a device may be protected from external moisture or foreign substances, thereby improving the electrical and optical reliability of the device. When the thickness is less than or equal to 500 nm, it is possible to reduce stress applied to the semiconductor device, to prevent a decrease in optical and electrical reliability of the semiconductor device, and to reduce costs of the semiconductor device, which are increased by an increase in a process time of the semiconductor device.

Uneven portions may be formed on the upper surface of the semiconductor structure 520. The uneven portions enable extraction efficiency of light emitted from the semiconductor structure 520 to be improved. The uneven portions may have different average heights according to ultraviolet light wavelengths. The uneven portions may have heights in a range of about 300 nm to 800 nm in the case of UV-C, and light extraction efficiency may be improved when an average height thereof is in a range of about 500 nm to 600 nm.

Further, the semiconductor device 10E according to the fifth embodiment may be a modified example in which the structure of the first insulating layer or the second insulating layer is modified into a vertical form in the semiconductor device according to the fourth embodiment described above. In addition, the above contents may be equally applied to a sixth embodiment and a seventh embodiment, which will be described below.

Referring to FIG. 12, a width Wa of the second-third insulating layer 532c may increase toward a lower portion thereof. Further, a thickness Ha of the second-third insulating layer 532c may decrease from a lower portion of the first insulating layer 531 toward the edge of the second recess 529.

Accordingly, a maximum thickness Hk of the second-third insulating layer 532c may be greater than a maximum thickness Hl of the second-second insulating layer 532b. In addition, the maximum thickness Hk of the second-third insulating layer 532c may be less than a height h1 of the second recess 529. As a result, a height difference caused by a step of the second recess 529, which is generated by increasing the thickness of the second-third insulating layer 532c toward the edge of the second recess 529, may be reduced. Further, as used herein, each of the thickness and the height refers to a length in the vertical direction (X-axis direction), and the width refers to a length in the horizontal direction (Y-axis direction).

Thus, the height h1 of the second recess 529 may be greater than a height difference h2 of a lower surface BS2 of the second-third insulating layer 532c. Here, the height difference of the lower surface BS2 of the second-third insulating layer 532c means a height difference between a surface BSA, which is located at an uppermost portion of the lower surface BS2 excluding the through hole GH, and a surface BSB that is located at a lowermost portion of the lower surface BS2 excluding the through hole GH. Specifically, a height ratio between the height h1 of the second recess 529 and the height difference h2 of the lower surface BS2 of the second-third insulating layer 532c may be in a range of 1:0 to 1:0.2. When the height ratio is out of the above range, the layer disposed below the second-third insulating layer 532c has a height difference along the lower surface BS2 of the second-third insulating layer 532c, and thus there is a problem that voids are easily generated. In addition, there is a problem that the reliability of the semiconductor device is degraded.

With such a configuration, the height difference is reduced at an interface between the second-third insulating layer 532c and the second conductive layer 565 below the second-third insulating layer 532c, so that each layer may be flat, thereby suppressing voids generated at the interface of each layer below the second-third insulating layer 532c. Furthermore, by suppressing the voids, bonding, thermal resistance, and the like at the interface may be improved, so that the reliability of the semiconductor device may be improved.

Here, the second-third insulating layer 532c may include the through hole GH disposed at the center of the second recess 529. The through hole GH may extend in the vertical direction (X-axis direction) in the second recess 529. In addition, an upper surface of the first electrode 542 is exposed by the through hole GH, and the second conductive layer 565 is disposed in the through hole GH, so that the second conductive layer 565 may be electrically connected to the first electrode 542.

Further, the through hole GH overlaps the first electrode 542 in the vertical direction (X-axis direction), and thus a length of the second conductive layer 565 in the through hole GH may be minimized. Accordingly, a resistance due to the second conductive layer 565 may be minimized, thereby improving the light output of the semiconductor device.

The height h1 of the second recess 529 in the vertical direction (X-axis direction) may be the same as the height h1 of the first recess 528 in the vertical direction (X-axis direction). In the present specification, a description will be made on the basis of the above description. Accordingly, the second recess 529 may overlap the first recess 528 in the horizontal direction (Y-axis direction). In addition. an inclination angle θ₁ of the second recess 529 may be equal to an inclination angle θ₂ of the first recess 528. Here, the inclination angle θ₁ of the second recess 529 and the inclination angle θ₂ of the first recess 528 may be an angle between the first insulating layer 531 and a horizontal plane (XZ plane).

With such a configuration, the first recess 528 and the second recess 529 may be simultaneously formed in the same process operation. Thus, the semiconductor device 10E according to the fifth embodiment may be implemented by a simplified process. However, the present invention is not limited to such a process. That is, when a minimum length of the first recess 528 is different from a minimum length of the second recess 529, the first recess 528 and the second recess 529 may be formed by different processes. Further. the inclination angle θ₁ of the second recess 529 may be different from the inclination angle θ₂ of the first recess 528.

In addition, the inclination angle θ₁ of the second recess 529 may be in a range of 70° to 90°. When the above-described range is satisfied, the formation of the first electrode 542 on an upper surface of the second recess 529 may be facilitated, and a large number of second recesses 529 may be formed.

When the inclination angle θ₁ of the second recess 529 is less than 70°, an area of the active layer 526 to be removed may increase, but an area in which the first electrode 542 is disposed may decrease. Accordingly, current injection characteristics may be degraded, and luminous efficiency may be lowered. Accordingly, a ratio between the areas of the first electrode 542 and the second electrode 546 may be adjusted using the inclination angle θ₁ of the second recess 529.

Further, the inclination angle θ₂ of the first recess 528 may be in a range of 70° to 90°. The inclination angle θ₂ of the first recess 528 may be an angle between the first insulating layer 531 and a plane (YZ plane). When the inclination angle θ₂ of the first recess 528 is out of the above range, the efficiency upwardly reflecting light, which moves laterally, may be reduced.

Further, the maximum width W1 of the second recess 529 may be in a range of 38 μm to 60 μm. When the width W1 of the second recess 529 is greater than or equal to 38 μm, it is possible to secure a process margin for securing an area in which the first electrode 542 is electrically connected to the first conductive semiconductor layer 524 while the first electrode 542 is disposed inside the second recess 529. When the width W1 of the second recess 529 is less than or equal to 60 μm, it is possible to prevent the volume of the active layer 526 from decreasing due to the arrangement of the first electrode 542, and thus light emission efficiency may be degraded.

In addition, within the above-described range, a plurality of first electrodes 542 may be disposed to be advantageous for current spreading. The maximum width W1 of the second recess 529 may be defined as a greatest area of the second recess by being disposed below the second conductive semiconductor layer 527. In addition, the width W1 of the second recess 529 may be a diameter when the second recess 529 is formed in a circular shape, and may refer to a maximum width when the second recess 529 is formed in an elliptical or polygonal structure.

In addition, a minimum width W2 of the second recess 529 may be a minimum width of the second recess 529 in contact with the first conductive semiconductor layer 524.

Further, a width W3 of the first electrode 542 may be in a range of 24 μm to 50 μm. When the above-described range is satisfied, current spreading may be facilitated and a large number of first electrodes 542 may be disposed. When the width W3 of the first electrode 542 is greater than or equal to 24 μm, the amount of current injected into the first conductive semiconductor layer 524 may be sufficiently secured. When the width W3 of the first electrode 542 is less than or equal to 50 μm, a sufficient number of first electrodes 542, which are disposed in the first conductive semiconductor layer 524, may be secured, so that current spreading characteristics may be secured. In addition, the width W3 of the first electrode 542 may be a diameter when the first electrode 542 is formed in a circular shape, and may refer to a maximum width when the first electrode 542 is formed in an elliptical or polygonal structure. In addition, as described above, the width may be a length in the horizontal direction (Y-axis direction).

A thickness of the second electrode 546 may be smaller than a thickness of the first insulating layer 531. Accordingly, step coverage characteristics of the first conductive layer 550 and second insulating layer 532, which surround the second electrode 546, may be secured, and the reliability of the semiconductor device 10E may be improved. The second electrode 546 may be spaced apart from the first insulating layer 531 by a first separation distance D1 of 1 μm to 4 μm. When the first separation distance D1 is greater than or equal to 1 μm, a process margin for a process of disposing the second electrode 546 between the first insulating layers 531 may be secured. Accordingly, the electrical and optical characteristics and the reliability of the semiconductor device 10E may be improved. When the first separation distance D1 is less than or equal to 4 μm, an entire area, in which the second electrode 546 may be disposed, may be secured, and operating voltage characteristics of the semiconductor device 10E may be improved.

Further, the first conductive layer 550 may be in contact with upper and side surfaces of the second electrode 546 and upper and side surfaces of the first insulating layer 531 within the first separation distance D1. Further, a region in which the first conductive layer 550 is in contact with the second conductive semiconductor layer 527 within the first separation distance D1 to form a Schottky junction may be present, and current spreading may be facilitated by forming the Schottky junction. However, the present invention is not limited such a configuration, and the first conductive layer 550 may be freely disposed within a range in which a resistance between the first conductive layer 550 and the second conductive semiconductor layer 527 is higher than a resistance between the second electrode 546 and the second conductive semiconductor layer 527.

Referring to FIG. 13, a width Wb of the second-first insulating layer 532a may increase toward the second conductive layer 565. Further, a thickness Hb of the second-first insulating layer 532a may decrease from the lower portion of the first insulating layer 531 toward the edge of the first recess 528.

Accordingly, a maximum thickness Hm of the second-first insulating layer 532a may be greater than the maximum thickness Hl of the second-second insulating layer 532b at the central portion C1 of the first recess 528. In addition, the maximum thickness Hk of the second-first insulating layer 532a may be greater than the height h1 of the first recess 528. As a result, a height difference caused by a step of the first recess 528, which is generated by increasing the thickness of the second-first insulating layer 532a toward the edge of the first recess 528, may be reduced.

Thus, the height h1 (FIG. 12) of the first recess 528 may be greater than a height difference h3 of a lower surface BS2 of the second-first insulating layer 532a. Here, the height difference h3 of the lower surface BS2 of the second-first insulating layer 532a means a height difference between a surface BSC, which is located at an uppermost portion of the lower surface BS2, and a surface BSD that is located at a lowermost portion of the lower surface BS2. Specifically, a height ratio between the height h1 of the second recess 529 and the height difference h3 of the lower surface BS2 of the second-first insulating layer 532a may be in a range of 1:0 to 1:0.2. When the height ratio is out of the above range, the layer disposed below the second-first insulating layer 532a has a height difference along the lower surface BS2 of the second-first insulating layer 532a, and thus there is a problem that voids are easily generated. In addition, there is a problem that the reliability of the semiconductor device is degraded.

That is, with such a configuration, the height difference is reduced at the interface between the second-first insulating layer 532a and the second conductive layer 565 below the second-first insulating layer 532a, so that each layer may be flat, thereby suppressing voids generated at the interface of each layer below the second-first insulating layer 532a. In particular, voids generated in the bonding layer 560 may be suppressed in the process of bonding between the substrate 570 and the second conductive layer 565. Furthermore, by suppressing the voids, bonding, thermal resistance, and the like at the interface may be improved, so that the reliability of the semiconductor device may be improved.

Since the entire width of the second-first insulating layer 532a increases toward a lower portion in the first recess 528, when a plurality of layers are formed, even when defects occur at the interface of each layer, it is possible to easily block the defects from being propagated to other layers. Further, the first recess 528 may be spaced apart from an outer side surface of the semiconductor structure 520 by a separation distance W4 of 3 μm to 5 μm. However, the separation distance may be varied depending on the size of the semiconductor device or the semiconductor structure. Further, an upper surface of the first recess 528 may have a minimum width W5 of 2 μm to 8 μm in the horizontal direction.

Further, a maximum height h5 from the lower surface BS2 of the second-first insulating layer 532a to an upper surface of the second-first insulating layer 532a in the vertical direction (X-axis direction) in the first recess 528 may be in a range of 1.7 μm to 2.1 μm.

Further, a maximum height h6 of the first insulating layer 531 from the lower surface BS2 in the vertical direction (X-axis direction) in the first recess 528 may be in a range of 2.4 μm to 2.6 μm.

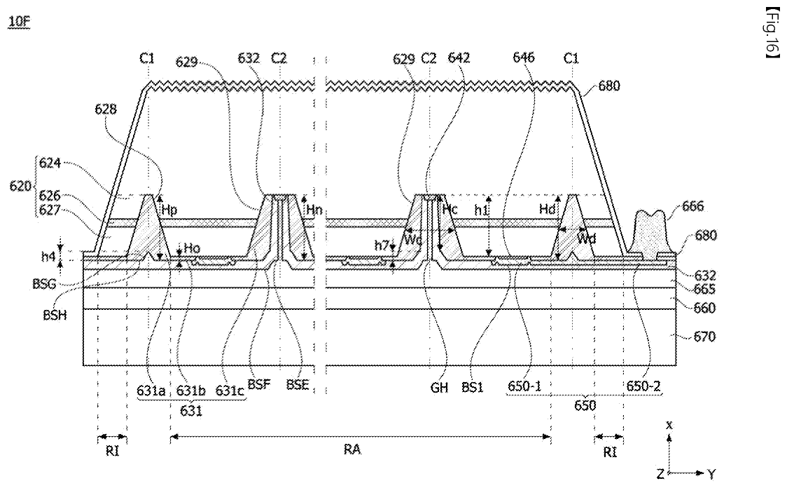

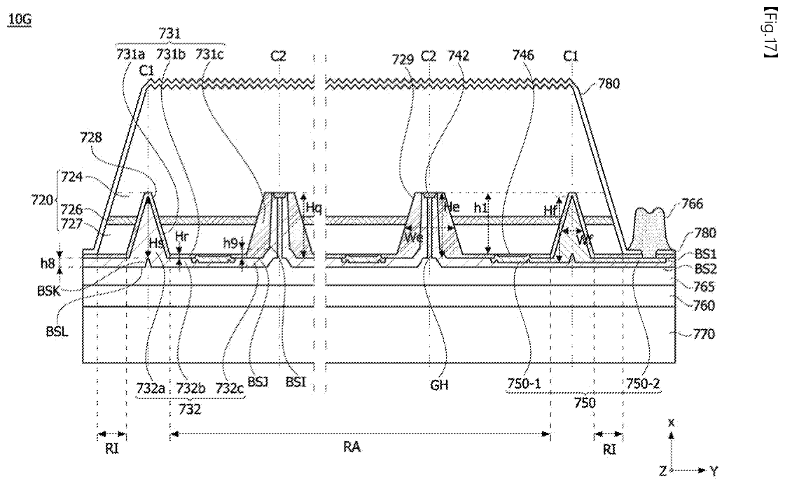

FIG. 14 is a plan view of the semiconductor device according to the fifth embodiment, and FIG. 15 is an enlarged view of portion K in FIG. 14.

Referring to FIG. 14, when a GaN-based semiconductor structure 520 emits ultraviolet light, the GaN-based semiconductor structure 520 may include Al. When an Al composition of the semiconductor structure 520 is increased, current spreading characteristics in the semiconductor structure 520 may be degraded. Further, when the active layer 526 includes Al and emits ultraviolet light, the amount of light emitted through a side surface of the active layer 526 increases (a TM mode), as compared with a GaN-based blue light-emitting device. The TM mode may occur mainly in an ultraviolet semiconductor device that generates ultraviolet light.

The ultraviolet semiconductor device has reduced current spreading characteristics as compared to a GaN-based blue semiconductor device. Accordingly, a relatively larger number of first electrodes 542 and second recesses 529 need to be disposed in the ultraviolet semiconductor device than in the GaN-based blue semiconductor device.

When the Al composition is increased, current spreading characteristics may be degraded. That is, a current is distributed only in the vicinity of the first electrode 542, and a current density may be drastically lowered at a position away from the first electrode 542. Accordingly, an effective light-emitting region P2 may be reduced in size.

The effective light-emitting region P2 may be defined as a region ranging to a boundary point at which a current density is 40% or less with respect to a current density at the center of the first electrode 542 having the highest current density. For example, the effective light-emitting region P2 may be adjusted according to a level of an injected current and the Al composition in a region within 40 μm from the center of the second recess 529.

Since a low current density region P3 has a low current density, the amount of light emitted by the low current density region P3 may be lower than the effective light-emitting region P2. Accordingly, the light output may be improved by further arranging the first electrode 542 and the second recess 529 in the low current density region P3 having a low current density or using a reflective structure.

In general, a GaN-based semiconductor device that emits blue light has relatively good current spreading characteristics, and thus areas of the second recess 529 and the first electrode 542 may preferably be minimized. This is because an area of the active layer 526 becomes smaller as the areas of the second recess 529 and the first electrode 542 become larger. However, in the embodiment, since current spreading characteristics are relatively poor due to a high Al composition, even when the area of the active layer 526 is sacrificed, the low current density region P3 may be preferably reduced by increasing the area and/or number of first electrodes 542, or the reflective structure may be preferably disposed in the low current density region P3.

Further, when the number of second recesses 529 is increased, the second recesses 529 may be arranged in a zigzag form instead of being linearly arranged in a horizontal or vertical direction. In this case, the area of the low current density region P3 may be reduced and thus most of the active layer 526 may participate in light emission.

Further, the first region RA may overlap the effective light-emitting region P2, and thus the light output may be maintained. In addition, the second region RI may be disposed to extend along the outer side surface of the semiconductor structure 520, so that the second region RI may not overlap the effective light-emitting region P2.

Referring to FIG. 15, a minimum width W6 of the first recess 528 may be less than the minimum width W1 of the second recess 529. Specifically, a width ratio of the minimum width W6 of the first recess 528 and the minimum width W1 of the second recess 529 may be in a range of 1:5 to 1:19.

When the width ratio of the minimum width W6 of the first recess 528 and the minimum width W1 of the second recess 529 is less than 1:5, there is a limitation that oxidation is facilitated due to delamination. In addition, when the width ratio of the minimum width W6 of the first recess 528 and the minimum width W1 of the second recess 529 is greater than 1:19, there is a problem in that the number of second recesses 529 for current spreading is reduced, so that the light output is reduced.

Further, as described above, the second recess 529 may have a central portion C2. In addition, the central portion C2 of the second recess 529 may be the same as the center of the first electrode 542 inside the second recess 529, and a distance L from the center of the first electrode 542 to a boundary point having a current density of 40% or less of a current density at the center of the first electrode 542 may be greater than a width W7 between the central portions C2 of the adjacent second recesses 529. Specifically, the width W7 between the central portions C2 of the adjacent second recesses 529 may be at least twice the distance L to the boundary point. With such a configuration, current may be easily injected so that the light output may be improved.

In addition, a minimum width W8 between the first recess 528 and the second recess 529 closest to the first recess 528 may be greater than the distance L to the boundary point. Thus, the current injected through the second recess 529 may be located so that spreading is not disturbed due to the first recess 528, so that the light output may not be reduced even though the semiconductor device has the first recess 528.

FIG. 16 is a conceptual diagram of a semiconductor device according to a sixth embodiment.

Referring to FIG. 16, a semiconductor device 10F according to the sixth embodiment may include a semiconductor structure 620 including a first conductive semiconductor layer 624, a second conductive semiconductor layer 627, and an active layer 626, a first insulating layer 631 partially disposed on a lower portion of the semiconductor structure 620, a first electrode 642 electrically connected to the first conductive semiconductor layer 624, a second electrode 646 electrically connected to the second conductive semiconductor layer 627, a first conductive layer 650 electrically connected to the second electrode 646 and disposed below the first insulating layer 631, a second insulating layer 632 disposed below the first conductive layer 650, a second conductive layer 665 disposed below the second insulating layer 632, a bonding layer 660 disposed below the second conductive layer 665, and a substrate 670 disposed below the bonding layer 660.

Specifically, in the semiconductor device 10F according to the sixth embodiment, the first insulating layer 631 may include a first-first insulating layer 631a disposed at a position corresponding to a first recess 628, a first-third insulating layer 631c disposed at a position corresponding to a second recess 629, and a first-second insulating layer 631b other than the first-first insulating layer 631a and the first-third insulating layer 631c. That is, the first-second insulating layer 631b may correspond to the outside of each of the first recess 628 and the second recess 629. In other words, the first-first insulating layer 631a overlaps the first recess 628 in the vertical direction (X-axis direction) in the first insulating layer 631, and the first-second insulating layer 631b does not overlap the first recess 628 and the second recess 629 in the vertical direction (X-axis direction), and the first-third insulating layer 631c overlaps the second recess 629 in the vertical direction (X-axis direction).

First, an entire width of the first-third insulating layer 631c may increase toward a lower portion thereof. That is, a width We of the first-third insulating layer 631c may increase toward the second conductive layer 665. Further, a thickness Hc of the first-third insulating layer 631c may decrease from the lower portion of the semiconductor structure 620 toward an edge of the second recess 629.

Accordingly, a maximum thickness Hn of the first-third insulating layer 631c may be greater than a maximum thickness Ho of the first-second insulating layer 631b. In addition, the maximum thickness Hn of the first-third insulating layer 631c may be less than a height h1 of the second recess 629. As a result, since the height of the first-third insulating layer 631c increases toward a central portion C2 of the second recess 629, a height difference generated due to a step of the second recess 629 may be compensated for, thereby compensating for a height difference of the interface of each layer disposed below the first-third insulating layer 631c.

Further, the height h1 of the second recess 629 may be greater than a height difference h7 of a lower surface BS1 of the first-third insulating layer 631c. Here, the height difference h7 of the lower surface BS1 of the first-third insulating layer 631c means a height difference between a surface BSE, which is located at an uppermost portion of the lower surface BS1 excluding a through hole GH, and a surface BSF that is located at a lowermost portion of the lower surface BS1 excluding the through hole GH. Specifically, a height ratio between the height h1 of the second recess 629 and the height difference h7 of the lower surface BS1 of the first-third insulating layer 631c may be in a range of 1:0 to 1:0.2. When the height ratio is out of the above range, the layer disposed below the first-third insulating layer 631c has a height difference along the lower surface BS1 of the first-third insulating layer 631c, and thus there is a problem that voids are easily generated. In addition, there is a problem that the reliability of the semiconductor device is degraded.

With such a configuration, the height difference is reduced at the interface between the first-third insulating layer 631c and the second conductive layer 665 below the first-third insulating layer 631c, so that each layer may be flat, thereby suppressing voids generated at the interface of each layer below the first-third insulating layer 631c. Furthermore, by suppressing the voids, bonding, thermal resistance, and the like at the interface may be improved, so that the reliability of the semiconductor device may be improved.

With such a configuration, in the first conductive layer 650, the second insulating layer 632, the second conductive layer 665, the bonding layer 660, and the substrate 670 that are disposed below the first-third insulating layer 631c, the interface of each element may be flat, thereby suppressing voids generated at the interface of each layer below the first insulating layer 631. In particular, by suppressing the voids, bonding, thermal resistance, and the like at the bonding layer 660 may be improved, so that the reliability of the semiconductor device may be improved.

Further, the through hole GH of the second insulating layer 632 disposed at the center of the second recess 629 may extend in the vertical direction (X-axis direction) in the second recess 629. Accordingly, the through hole GH overlaps the first electrode 642 in the vertical direction (X-axis direction), and thus a length of the second conductive layer 665 in the through hole GH may be minimized. Accordingly, a resistance due to the second conductive layer 665 may be minimized, thereby improving light output of the semiconductor device.

A width Wd of the first-first insulating layer 631a may increase toward a lower portion in the first recess 628. Specifically, the width Wd of the first-first insulating layer 631a may increase toward the second conductive layer 665. Further, a thickness Hd of the first-first insulating layer 631a may decrease from the lower portion of the semiconductor structure 620 toward an edge of the first recess 628.

Accordingly, a maximum thickness Hp of the first-first insulating layer 631a may be greater than the maximum thickness Ho of the first-second insulating layer 631b at a central portion C1 of the first recess 628. In addition, the maximum thickness Hp of first-first insulating layer 631a may be less than a height h1 of the first recess 628. As a result, a height difference caused by a step of the first recess 628, which is generated by increasing the height of the first-first insulating layer 631a from the central portion C1 of the first recess 628 toward the edge of the first recess 628, may be reduced.

Further, the height h1 of the second recess 629 may be greater than a height difference h4 of a lower surface BS1 of the first-first insulating layer 631a. Here, the height difference h3 of the lower surface BS1 of the first-first insulating layer 631a means a height difference between a surface BSG, which is located at an uppermost portion of the lower surface BS1, and a surface BSH that is located at a lowermost portion of the lower surface BS1. Specifically, a height ratio between the height h1 of the second recess 629 and the height difference h4 of the lower surface BS1 of the first-first insulating layer 631a may be in a range of 1:0 to 1:0.2. When the height ratio is out of the above range, the layer disposed below the first-first insulating layer 631a has a height difference along the lower surface BS1 of the first-first insulating layer 631a, and thus there is a problem that voids are easily generated. In addition, there is a problem that the reliability of the semiconductor device is degraded.

That is, with such a configuration, the height difference is reduced at the interface between the first-first insulating layer 631a and the second conductive layer 665 below the first-first insulating layer 631a, so that each layer may be flat, thereby suppressing voids generated at the interface of each layer below the first-first insulating layer 631a. In particular, voids generated in the bonding layer 660 may be suppressed in the process of bonding between the substrate 670 and the second conductive layer 665. Furthermore, by suppressing the voids, bonding, thermal resistance, and the like at the interface may be improved, so that the reliability of the semiconductor device may be improved.

In addition, since a height difference in an upper surface or a lower surface of the first conductive layer 650 is also reduced, the first conductive layer 650 may not extend toward the semiconductor structure 620 along the shape of the first recess 628. Thus, since the first conductive layer 650 does not overlap the first recess 628 in the horizontal direction (Y-axis direction), an overlapping area between the first conductive layer 650 and the first recess 628 in the vertical direction (X-axis direction) may be minimized. That is, between the second electrode 646 and an electrode pad 666, a length of the first conductive layer 650 decreases and an electrical resistance decreases, so that electrical characteristics of the semiconductor device may be improved.

Further, since an entire width of the first insulating layer 631 increases toward the lower portion in the first recess 628, when a plurality of layers are formed, even when defects occur at the interface of each layer, it is possible to easily block the defects from being propagated to other layers.

In addition, except for the above description, the contents described in the fifth embodiment with reference to FIGS. 1 to 13 may be equally applied to the semiconductor device 10F according to the sixth embodiment.

FIG. 17 is a conceptual diagram of a semiconductor device according to a seventh embodiment.

A semiconductor device 10G according to the seventh embodiment may include a semiconductor structure 720 including a first conductive semiconductor layer 724, a second conductive semiconductor layer 727, and an active layer 726, a first insulating layer 731 partially disposed on a lower portion of the semiconductor structure 720, a first electrode 742 electrically connected to the first conductive semiconductor layer 724, a second electrode 746 electrically connected to the second conductive semiconductor layer 727, a first conductive layer 750 electrically connected to the second electrode 746 and disposed below the first insulating layer 731, a second insulating layer 732 disposed below the first conductive layer 750, a second conductive layer 765 disposed below the second insulating layer 732, a bonding layer 760 disposed below the second conductive layer 765, and a substrate 770 disposed below the bonding layer 760.

Specifically, in the semiconductor device 10G according to the seventh embodiment, the first insulating layer 731 may include a first-first insulating layer 731a disposed at a position corresponding to a first recess 728, a first-third insulating layer 731c disposed at a position corresponding to a second recess 729, and a first-second insulating layer 731b other than the first-first insulating layer 731a and the first-third insulating layer 731c. That is, the first-second insulating layer 731b may correspond to the outside of each of the first recess 728 and the second recess 729. In other words, the first-first insulating layer 731a overlaps the first recess 728 in the vertical direction (X-axis direction) in the first insulating layer 731, and the first-second insulating layer 731b does not overlap the first recess 728 and the second recess 729 in the vertical direction (X-axis direction), and the first-third insulating layer 731c overlaps the second recess 729 in the vertical direction (X-axis direction).

Further, the second insulating layer 732 may include a second-first insulating layer 732a disposed at a position corresponding to the first recess 728, a second-third insulating layer 732c disposed at a position corresponding to the second recess 729, and a second-second insulating layer 732b other than the second-first insulating layer 732a and the second-third insulating layer 732c. That is, the second-second insulating layer 732b may correspond to the outside of each of the first recess 728 and the second recess 729. In other words, the second-first insulating layer 732a overlaps the first recess 728 in the vertical direction (X-axis direction) in the second insulating layer 732, and the second-second insulating layer 732b does not overlap the first recess 728 and the second recess 729 in the vertical direction (X-axis direction), and the second-third insulating layer 732c overlaps the second recess 729 in the vertical direction (X-axis direction).

First, a width We of the first-third insulating layer 731c may increase toward the second conductive layer 765 in the second recess 729. Further, a thickness He of the first-third insulating layer 731c in the second recess 729 may decrease from the lower portion of the semiconductor structure 720 toward an edge of the second recess 729.

Accordingly, a maximum thickness Hq of the first-third insulating layer 731c may be greater than a maximum thickness Hr of the first-second insulating layer 731b. In addition, the maximum thickness Hq of the first-third insulating layer 731c may be less than a height h1 of the second recess 729. As a result, since the height of the first-third insulating layer 731c increases toward a central portion C2 of the second recess 729, a height difference generated due to a step of the second recess 729 may be compensated for, thereby compensating for a height difference of the interface of each layer disposed below the first-third insulating layer 731c.

Further, the height h1 of the second recess 729 may be greater than a height difference h9 of a lower surface BS1 of the first-third insulating layer 731c. Here, the height difference h9 of the lower surface BS1 of the first-third insulating layer 731c means a height difference between a surface BS1, which is located at an uppermost portion of the lower surface BS1 excluding a through hole GH, and a surface BSJ that is located at a lowermost portion of the lower surface BS1 excluding the through hole GH. Thus, it is possible to prevent the height difference between the lower surfaces of the first-third insulating layer 731c corresponding to the height of the second recess 729 from being formed. In addition, the reliability of the semiconductor device is improved by suppressing the generation of voids.

Further, since the height difference is reduced at the interface between the first-third insulating layer 731c and the second conductive layer 765 below the first-third insulating layer 731c, each layer may be flat, thereby suppressing voids generated at the interface of each layer below the first-third insulating layer 731c. Furthermore, by suppressing the voids, bonding, thermal resistance, and the like at the interface may be improved, so that the reliability of the semiconductor device may be improved.

Further, an entire width Wf of second-first insulating layer 732a may increase toward a lower portion thereof. Specifically, the width Wf of the second-first insulating layer 732a may increase toward the second conductive layer 765. Further, a thickness Hf of the second-first insulating layer 732a may decrease from a lower portion of the first insulating layer 731 toward an edge of the first recess 728.

Accordingly, a maximum thickness Hs of the second-first insulating layer 732a may be greater than the maximum thickness Hr of the second-second insulating layer 732b at a central portion C1 of the first recess 728. In addition, the maximum thickness Hs of the second-first insulating layer 732a may be less than a height h1 of the first recess 728. As a result, a height difference caused by a step of the first recess 728, which is generated by increasing the thickness of the second-first insulating layer 732a toward the edge of the first recess 728, may be reduced.

Thus, the height h1 of the first recess 728 may be greater than a height difference h8 of a lower surface BS2 of the second-first insulating layer 732a. Here, the height difference h8 of the lower surface BS2 of the second-first insulating layer 732a means a height difference between a surface BSK, which is located at an uppermost portion of the lower surface BS2, and a surface BSL that is located at a lowermost portion of the lower surface BS2. With such a configuration, the height difference of the lower surface of the second-first insulating layer 732a corresponding to the height of the second recess 729 may be prevented from forming. In addition, the reliability of the semiconductor device is improved by suppressing the generation of voids.

Further, the through hole GH of second-third insulating layer 732c the disposed at the center of the second recess 729 may extend in the vertical direction (X-axis direction) in the second recess 729. Accordingly, the through hole GH overlaps the first electrode 742 in the vertical direction (X-axis direction), and thus a length of the second conductive layer 765 in the through hole GH may be minimized. Accordingly, a resistance due to the second conductive layer 765 may be minimized, thereby improving light output of the semiconductor device.

Further, since the entire width of the second-first insulating layer 732a increases toward a lower portion in the first recess 728, when a plurality of layers are formed, even when defects occur at the interface of each layer, it is possible to easily block the defects from being propagated to other layers.

In addition, except for the above description, the contents described in the fifth embodiment with reference to FIGS. 1 to 13 may be equally applied to the semiconductor device 10G according to the seventh embodiment.

In addition, in the semiconductor device according to the present specification, the entire width of the second-third insulating layer 732c may increase toward the lower portion of the second recess 729, and the entire width of the first-first insulating layer 731a may increase toward the lower portion in the first recess 728.

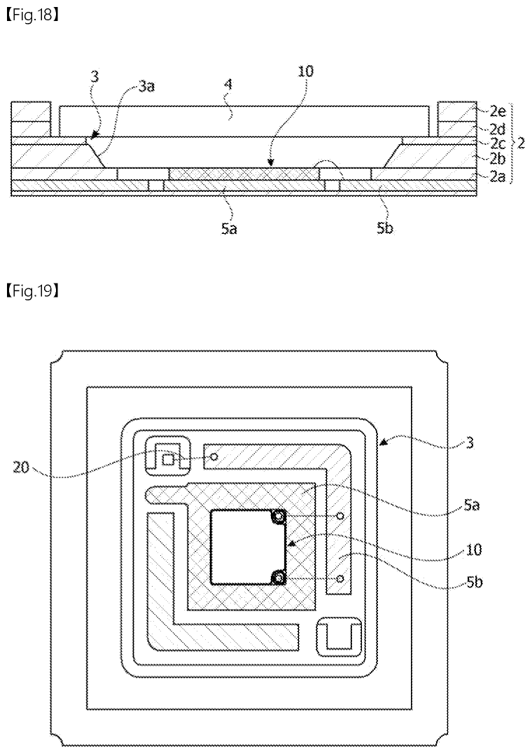

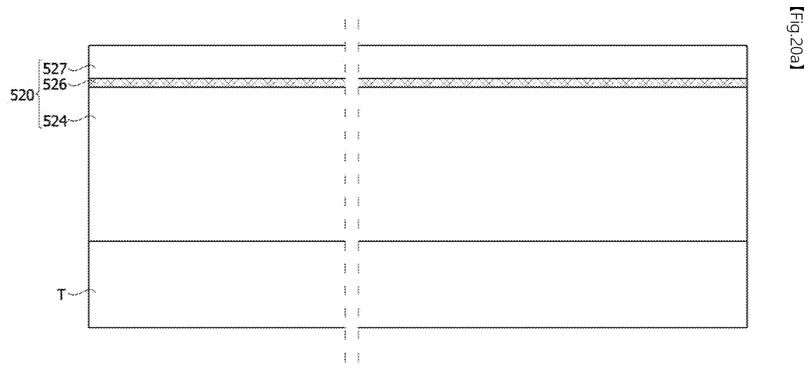

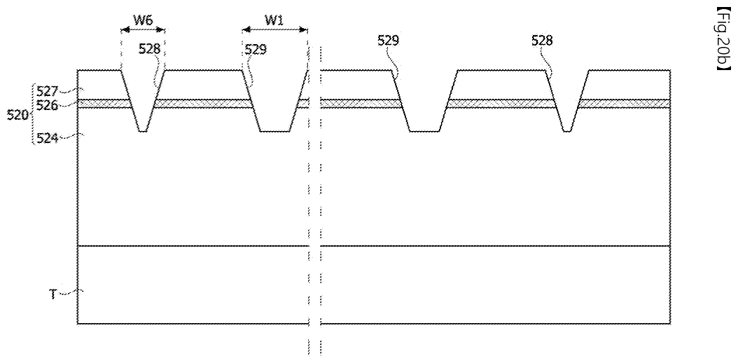

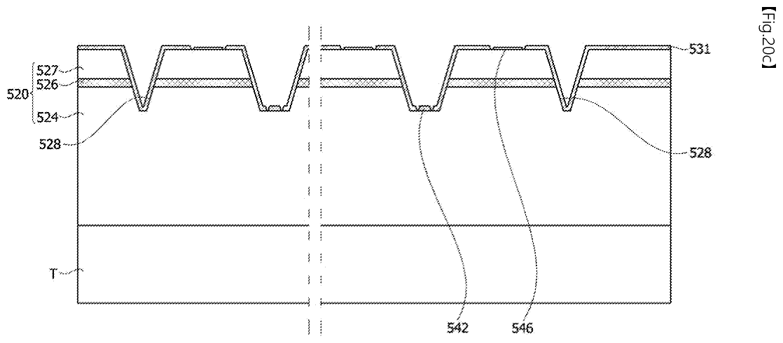

FIG. 18 is a conceptual diagram of a semiconductor device package according to another embodiment, and FIG. 19 is a plan view of the semiconductor device package according to another embodiment.

Referring to FIG. 18, the semiconductor device package may include a body 2 having a groove (opening) 3 formed therein, a semiconductor device 10 disposed in the body 2, and a pair of lead frames 5a and 5b which are disposed on the body 2 and electrically connected to the semiconductor device 10. The semiconductor device 10 may include all the above-described configurations. Here, all of the semiconductor devices of the above-described embodiments may be applied as the semiconductor device 10.

The body 2 may include a material or a coating layer that reflects ultraviolet light. The body 2 may be formed by stacking a plurality of layers 2a, 2b, 2c, 2d, and 2e. The plurality of layers 2a, 2b, 2c, 2d, and 2e may include the same material or different materials. As an example, the plurality of layers 2a, 2b, 2c, 2d, and 2e may include an aluminum material.

The groove 3 may be formed to be wider as a distance from the semiconductor device is increased, and a step 3a may be formed on an inclined surface thereof.

A light-transmitting layer 4 may cover the groove 3. The light-transmitting layer 4 may be made of a glass material, but the present invention is not necessarily limited thereto. A material for the light-transmitting layer 4 is not specifically limited as long as it is capable of effectively transmitting ultraviolet light. The inside of the groove 3 may be an empty space.

Referring to FIG. 19, the semiconductor device 10 may be disposed on a first lead frame 5a and may be connected to a second lead frame 5b using a wire 20. In this case, the second lead frame 5b may be disposed to surround a side surface of the first lead frame.

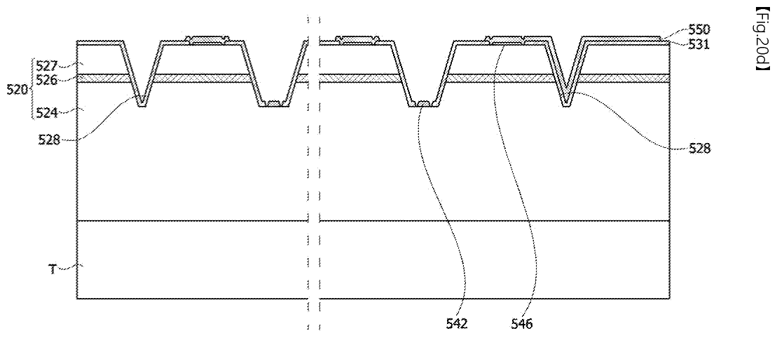

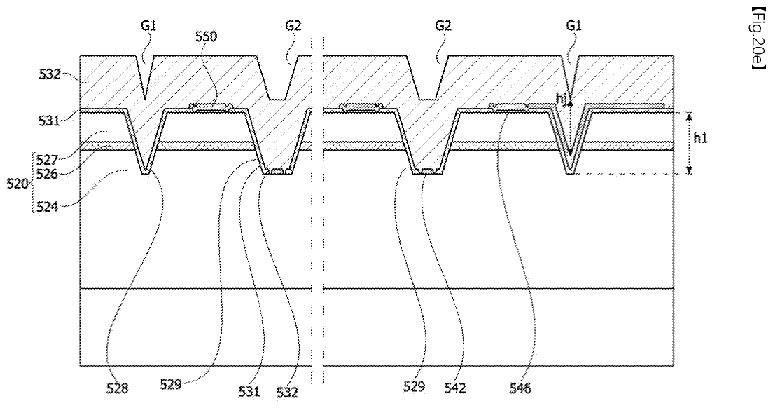

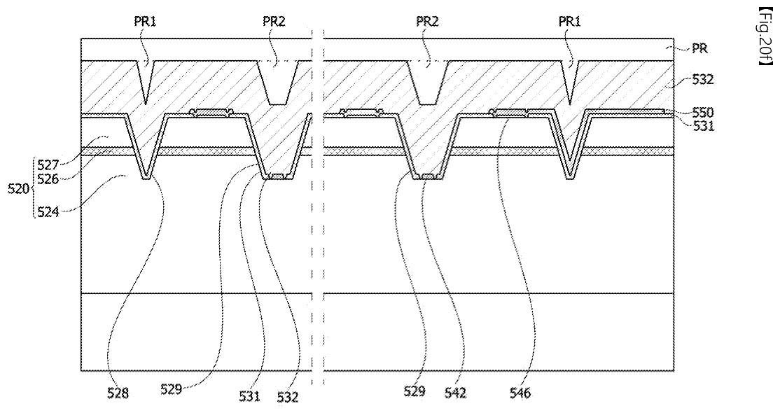

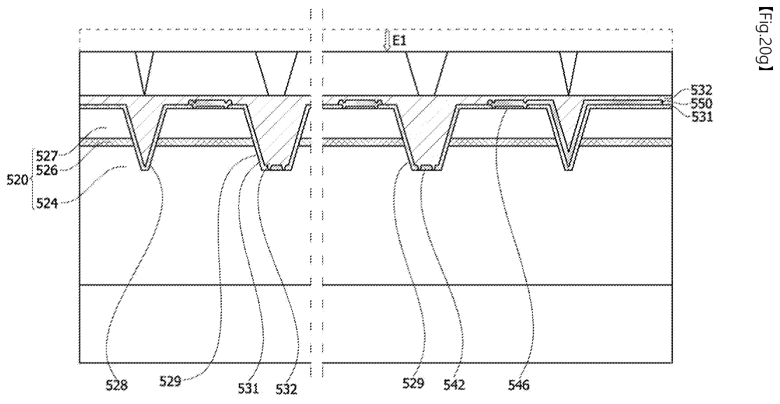

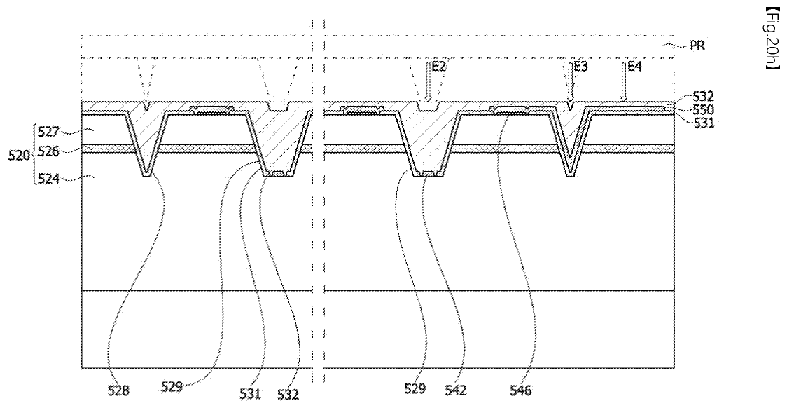

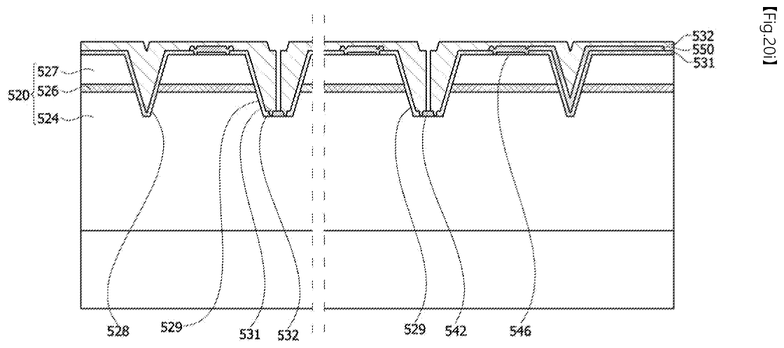

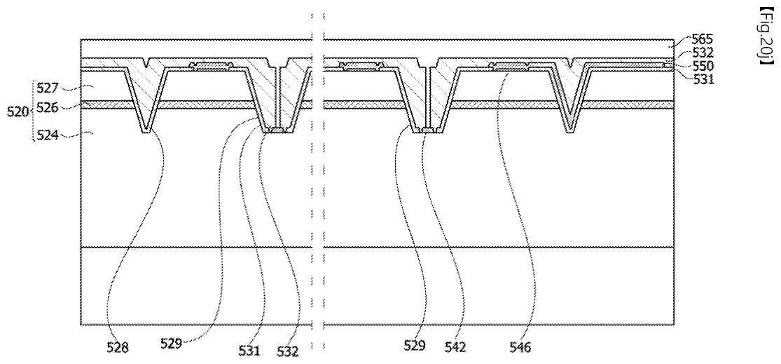

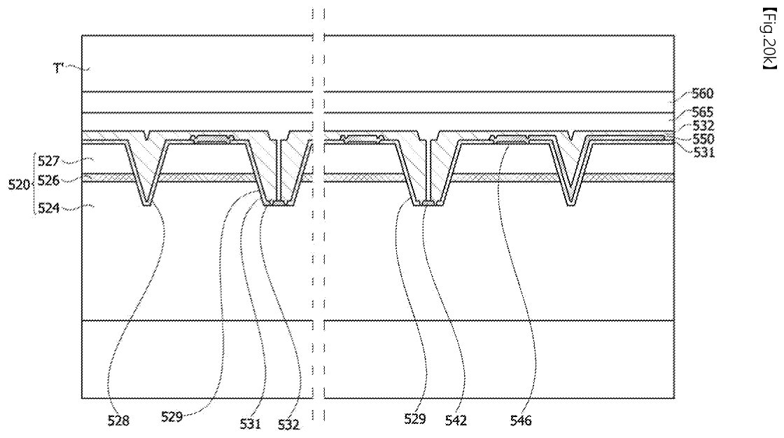

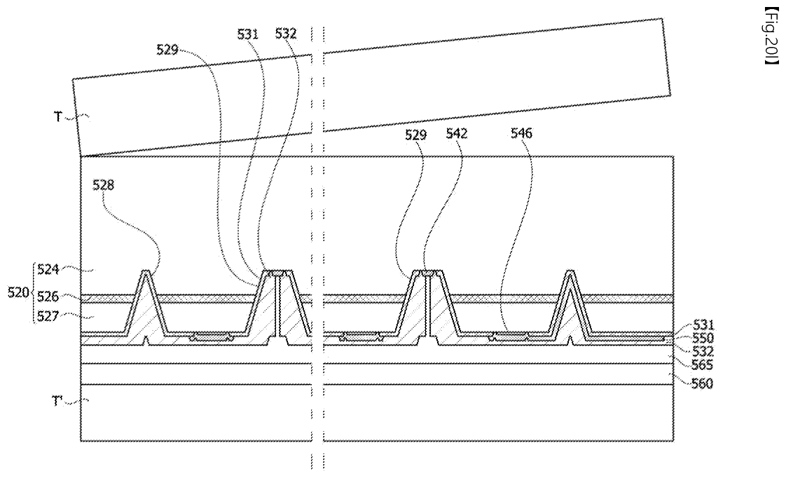

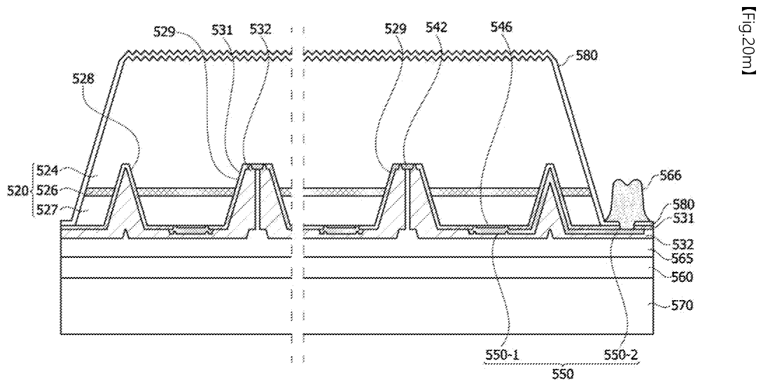

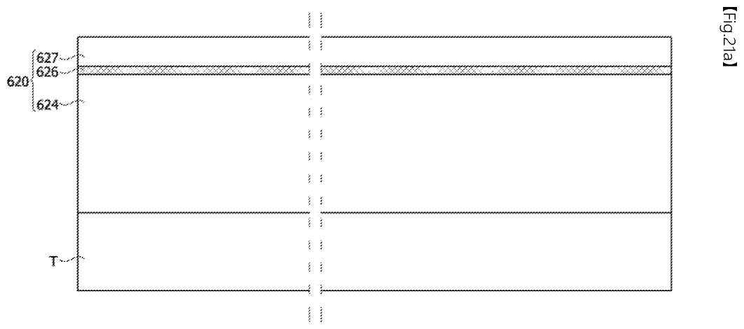

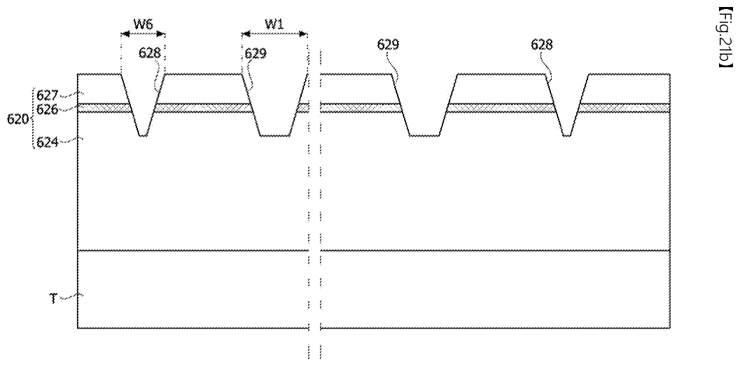

FIGS. 20A to 20M are sequence diagrams for describing a method of manufacturing the semiconductor device according to the fifth embodiment.

The method of manufacturing the semiconductor device according to the fifth embodiment includes growing a semiconductor structure, disposing a first recess and a second recess, which is located inward from the first recess, in the semiconductor structure, disposing a first insulating layer on the semiconductor structure, a first electrode in the second recess, and a second electrode on the semiconductor structure, disposing a first conductive layer on the semiconductor structure and the second electrode, disposing a second insulating layer on the first insulating layer and the first conductive layer, and disposing a second conductive layer, a bonding layer, and a substrate on the second insulating layer.

Further, the disposing of the second insulating layer may include disposing a second insulating layer including a groove on an upper surface thereof, disposing a photoresist in the groove, etching the second insulating layer to remove the groove, and removing the photoresist.

Each operation will be described below in detail with reference to FIGS. 20A to 20M.

First, referring to FIG. 20A, a semiconductor structure 520 may be grown. The semiconductor structure 520 may be grown on a first temporary substrate T. For example, a first conductive semiconductor layer 524, an active layer 526, and a second conductive semiconductor layer 527 may be grown on the first temporary substrate T.

The first temporary substrate T may be a growth substrate. For example, the first temporary substrate T may be made of at least one selected from among sapphire (Al₂O₃), SiC, GaAs, GaN, ZnO, Si, GaP, InP, and Ge, but the present invention is not limited to such a material.

Further, the semiconductor structure 520 may be formed using, for example, an MOCVD method, a CVD method, a PECV method, an MBE method, a HVPE method, or the like, but the present invention is not limited thereto.

Descriptions of the first conductive semiconductor layer 524, the active layer 526, and the second conductive semiconductor layer 527 may be the same as described above.

Referring to FIG. 20B, a first recess 528 and a second recess 529 may be disposed in the semiconductor structure 520. The first recess 528 and the second recess 529 may be formed by various etching methods as described above.

Specifically, the first recess 528 may be disposed along an edge of the semiconductor structure 520. Thus, as described above, the semiconductor structure 520 may be divided into a first region and a second region by the first recess 528.

In addition, as in the first recess 528, the second recess 529 is disposed to pass through the second conductive semiconductor layer 527 and the active layer 526 and to pass through even a partial region of the first conductive semiconductor layer 524 in the semiconductor structure 520.

Further, the second recess 529 may be formed simultaneously with the first recess 528 by etching. As a result, the first recess 528 and the second recess 529 are formed by one process, and thus processes may be minimized. Further, as described above, the first recess 528 and the second recess 529 may have the same inclination angle and the same thickness in a vertical direction. However, the first recess 528 and the second recess 529 may have different widths in a horizontal direction. For example, a minimum width W6 of the first recess 528 may be less than a minimum width W1 of the second recess 529. However, the present invention is not limited to such a process, and the first recess 528 and the second recess 529 may be disposed in the semiconductor structure 520 by different etching processes.

Referring to FIG. 20C, a first insulating layer 531, a first electrode 542, and a second electrode 546 may be disposed. First, the first insulating layer 531 may be disposed, and the first electrode 542 and the second electrode 546 may be disposed. However, the order of manufacturing the first insulating layer 531, the first electrode 542, and the second electrode 546 may be variously applied.

In an embodiment, the first insulating layer 531 is disposed on an upper surface of the semiconductor structure 520, and then the first insulating layer 531 may be removed at positions in which the first electrode 542 and the second electrode 546 are disposed in the first insulating layer 531. That is, portions of the first insulating layer 531 may be exposed so that the first electrode 542 and the second electrode 546 may be disposed.

For example, the first insulating layer 531 disposed in the second recess 529 may be partially removed to expose the first conductive semiconductor layer 524. Also, the first insulating layer 531 disposed inside the first recess 528 and in contact with the second conductive semiconductor layer 527 may be partially removed to expose the second conductive semiconductor layer 527. In addition, the first electrode 542 and the second electrode 546 may be disposed in regions through which the above-described first conductive semiconductor layer 524 and second conductive semiconductor layer 527 are exposed, respectively.

Accordingly, the first electrode 542 may be disposed on an upper surface of the first conductive semiconductor layer 524 and inside the second recess 529, and electrically connected to the first conductive semiconductor layer 524. In addition, the second electrode 546 may be disposed on an upper surface of the second conductive semiconductor layer 527 and electrically connected to the second conductive semiconductor layer 527.

Referring to FIG. 20D, a first conductive layer 550 may be disposed on the first insulating layer 531 and the second electrode 546. In this case, the first conductive layer 550 may be disposed to surround the second electrode 546. Accordingly, the first conductive layer 550 may be in contact with the second electrode 546 to be electrically connected to the second electrode 546.

Further, the first insulating layer 531 may electrically insulate the first conductive layer 550 from the first conductive semiconductor layer 524.

The first conductive layer 550 may be partially disposed on the first recess 528 and may extend toward the edge of the semiconductor structure 520. However, as described above, the first conductive layer 550 may extend toward an electrode pad and may have a region that does not overlap the first recess 528 in the vertical direction.

Further, the first conductive layer 550 may be etched so as not to be exposed to an outer side surface of the semiconductor device.

Referring to FIG. 20E, a second insulating layer 532 may be disposed on the semiconductor structure 520. In addition, the second insulating layer 532 may be disposed to surround the first conductive layer 550. In this case, the second insulating layer 532 may have grooves G1 and G2, which respectively face the first recess 528 and the second recess 529, in an upper surface thereof along the shapes of the first recess 528 and the second recess 529. That is, the upper surface of the second insulating layer 532 may extend downward on the first recess 528 and the second recess 529.

Further, the second insulating layer 532 may be disposed on the first insulating layer 531, the first conductive layer 550, and the first electrode 542 to surround the first insulating layer 531 and the first electrode 542. With such a configuration, even when a crack is generated in the first insulating layer 531, the second insulating layer 532 may secondarily protect the semiconductor structure 520.

Further, a height ratio between a height hj of the second insulating layer 532 and a height h1 of each of the first recess 528 and the second recess 529 may be in a range of 1:1.5 to 1:3. When the height ratio is less than 1:1.5, the upper surface of the second insulating layer 532 is not flat, an thus there is a limitation that voids are generated between the upper surface of the second insulating layer 532 and a bonding layer to be described below. That is, the reliability of the semiconductor device may be degraded. In addition, when the height ratio is greater than 1:3, there is a problem of increasing process cost and time at the time of etching.

Further, the second insulating layer 532 may include grooves in the upper surface thereof along the shapes of the first recess 528 and the second recess 529.

Referring to FIG. 20F, a photoresist PR may be disposed on the grooves G1 and G2 of the second insulating layer 532. The photoresist PR may be applied to the inside of each of the grooves G1 and G2 of the second insulating layer 532 and onto the second insulating layer 532. In an embodiment, the photoresist PR may include a first photoresist PR1 disposed in the groove G1 above the first recess 528 and a second photoresist PR2 disposed in the groove G2 above the second recess 529. The first photoresist PR1 and the second photoresist PR2 may be located in the first recess 528 and the second recess 529, respectively, to form a predetermined pattern.

The first photoresist PR1 may be smaller in than the second photoresist PR2. Further, the diameter and height of the first photoresist PR1, in a case in which the first photoresist PR1 overlaps the first conductive layer 550 in the vertical direction due to the first conductive layer 550, may be smaller than those in a case in which the first photoresist PR1 does not overlap the first conductive layer 550 in the vertical direction.

Referring to FIG. 20G, first etching may be performed on the photoresist PR. Since the first etching is performed on the photoresist PR, the same etching rate (E1) may be applied over the entire surface, and the etching may be performed by various etching methods, for example, wet or dry etching may be applied.

In addition, the first photoresist PR1 and the second photoresist PR2 may remain and the second insulating layer 532 may be exposed by etching.

Referring to FIG. 20H, secondary etching may be performed so that the grooves G1 and G2 of the second insulating layer 532 are removed.

Specifically, the etching may be performed on the first photoresist PR1 and the second photoresist PR2 at a first etching rate (E2 and E3).

However, the etching may be performed on the second insulating layer 532 at a second etching rate (E4). In this case, the first etching rate and the second etching rate are different from each other, and the first etching rate may be higher than the second etching rate. However, this may be changed according to the materials of the first photoresist PR1, the second photoresist PR2, and the second insulating layer 532.

A height difference in the upper surface of the second insulating layer 532 may be reduced by the etching. However, the upper surface of the second insulating layer 532 above the first recess 528 and the second recess 529 may have the height difference as described above. However, the height difference is less than the height of each of the first recess 528 and the second recess 529, and thus the upper surface of the second insulating layer 532 may be flat above the first recess 528 and the second recess 529.

Accordingly, gaps (voids) may be prevented from being generated at an interface with an element disposed on the second insulating layer 532. In addition, the generation of voids is suppressed so that bonding force, thermal resistance, and the like between the second insulating layer 532 and the element thereon may be improved, thereby improving the reliability of the semiconductor device.

Further, when the photoresist remains in the process, the photoresist may be removed by a stripper or the like, but the present invention is not limited thereto. In addition, the stripper may include a fluorine-based compound having chemical stability. However, the present invention is not limited to such a material.

Referring to FIG. 20I, the second insulating layer 532 may include a through hole GH to expose a portion of an upper surface of the first electrode 542. The through hole GH may be located on the first electrode 542 and may extend in the vertical direction. For example, the through hole GH may be disposed to overlap the first electrode 542 in the vertical direction.

Referring to FIG. 20J, a second conductive layer 565 may be disposed on the second insulating layer 532. The second conductive layer 565 may be disposed on the exposed upper surface of the first electrode 542. Thus, the second conductive layer 565 may be electrically connected to the first electrode 542. In addition, the second insulating layer 532 may electrically insulate the second electrode 546 from the second conductive layer 565.

Referring to FIG. 20K, a bonding layer 560 and a second substrate T′ may be disposed on the second conductive layer 565.

First, the bonding layer 560 may include a conductive material. As an example, the bonding layer 560 may include a material selected from the group consisting of gold, tin, indium, aluminum, silicon, silver, nickel, and copper, or an alloy thereof.

In addition, the second substrate T′ may be the same substrate as the substrate 570 in FIG. 1. Thus, as described with reference to FIG. 1, the second substrate T′ may be made of a conductive material. As an example, the second substrate T′ may include a metal or a semiconductor material. The second substrate T′ may include a metal having high electrical conductivity and/or thermal conductivity. In this case, heat generated during the operation of the semiconductor device may be rapidly discharged to the outside. In addition, when the second substrate T′ is made of a conductive material, the first electrode 542 may be supplied with a current from the outside through the second substrate T′.

The second substrate T′ may include a material selected from the group consisting of silicon, molybdenum, tungsten, copper, and aluminum or an alloy thereof.

Further, the bonding layer 560 and the second substrate T′ may be disposed on the second insulating layer 532 and may be flat along the upper surface of the second insulating layer 532. As a result, the generation of voids between the interfaces is suppressed so that the delamination caused by heat is suppressed, thereby improving the bonding force between each element of the semiconductor device.

In addition, referring to FIG. 20L, the first temporary substrate T may be separated from the semiconductor structure 520. For example, the first temporary substrate T may be separated from the semiconductor structure 520 by irradiating laser light onto the first temporary substrate T. However, the present invention is not limited to such a manner.

Referring to FIG. 20M, a passivation layer 580 may be disposed on upper and side surfaces of the semiconductor structure 520. As described above, the passivation layer 580 may have a thickness of 200 nm to 500 nm. When the thickness is greater than or equal to 200 nm, a device may be protected from external moisture or foreign substances, thereby improving the electrical and optical reliability of the device. When the thickness is less than or equal to 500 nm, it is possible to reduce stress applied to the semiconductor device, to prevent a decrease in optical and electrical reliability of the semiconductor device, and to reduce costs of the semiconductor device, which are increased by an increase in a processing time of the semiconductor device. However, the present invention is not limited to such a configuration.

Further, before the passivation layer 580 is disposed, uneven portions may be formed on the upper surface of the semiconductor structure 520. The uneven portions enable extraction efficiency of light emitted from the semiconductor structure 520 to be improved. Heights of the uneven portions may be differently adjusted according to a wavelength of light generated in the semiconductor structure 520. In addition, an electrode pad 566 may be formed through a pattern.

However, the planarization process described with reference to FIGS. 20E to 20H may be equally applied to the first insulating layer 531 in addition to the second insulating layer 532 as described above with reference to FIGS. 16 and 17.

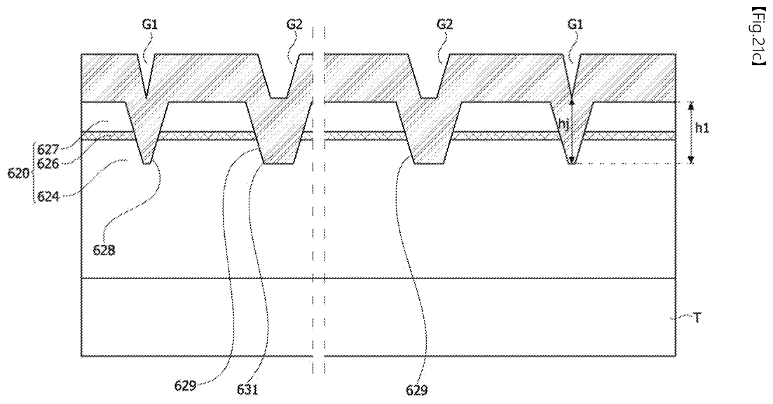

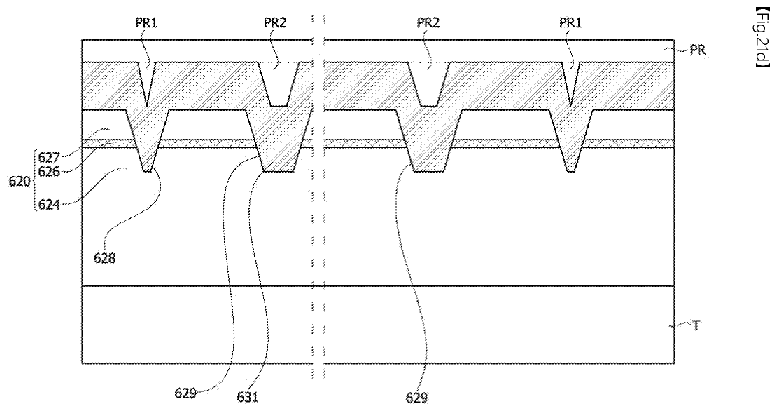

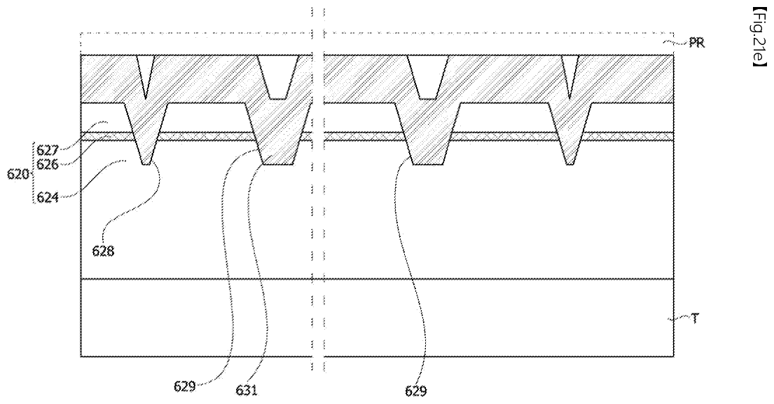

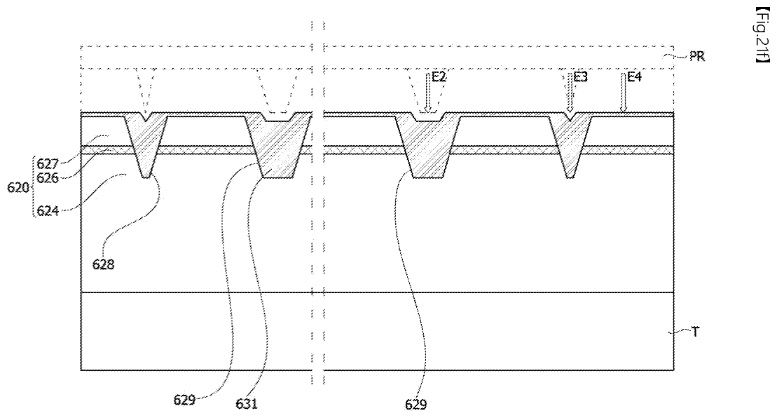

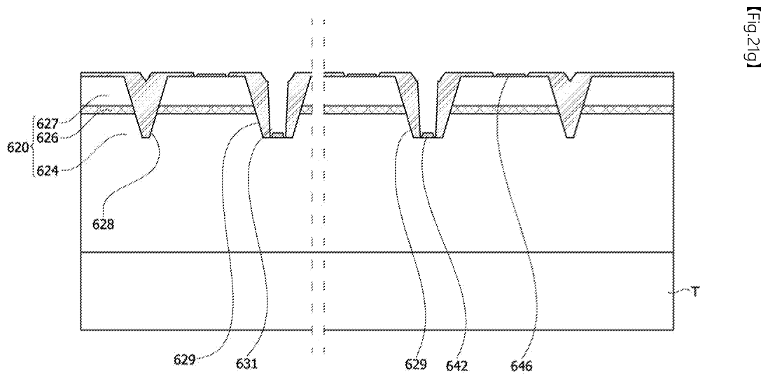

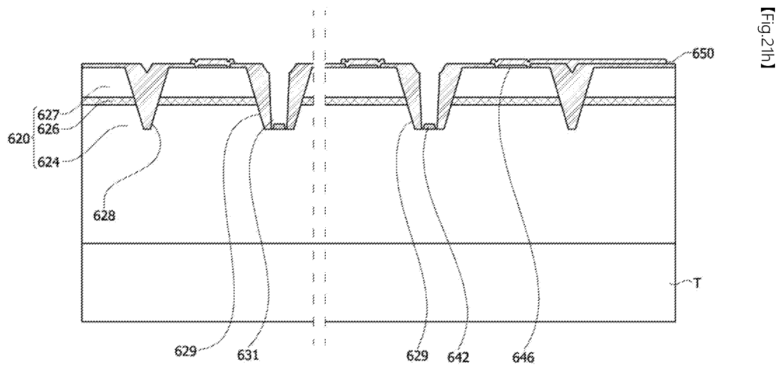

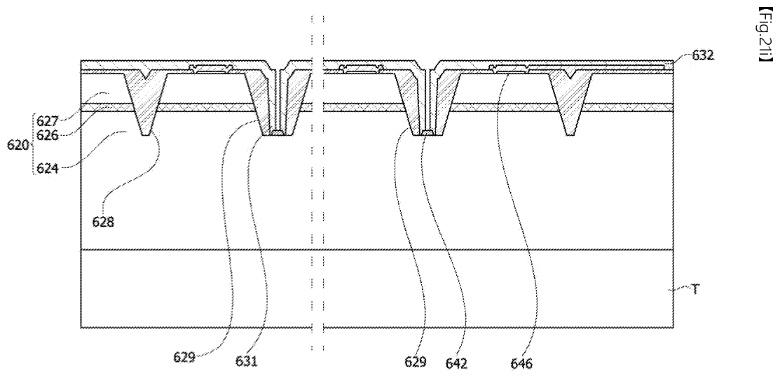

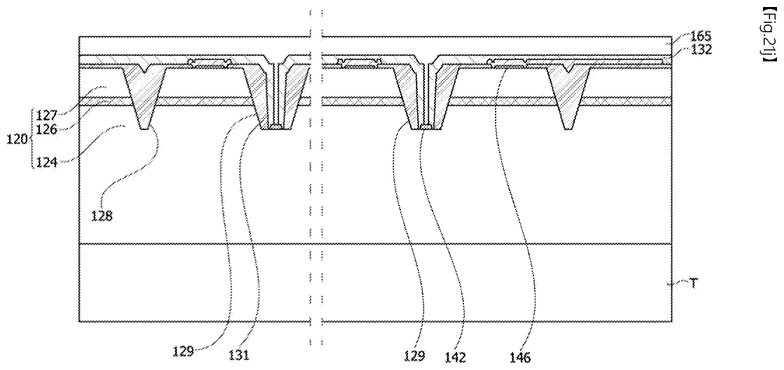

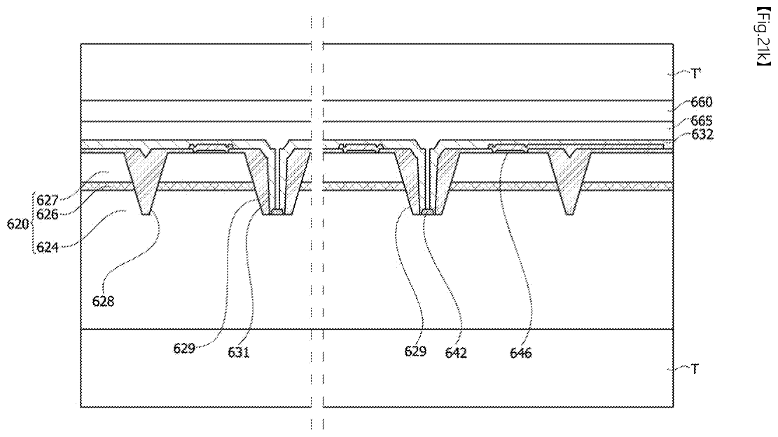

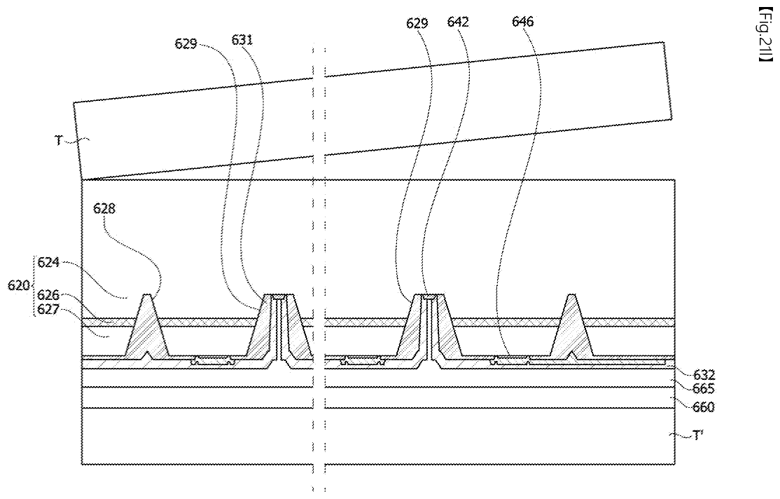

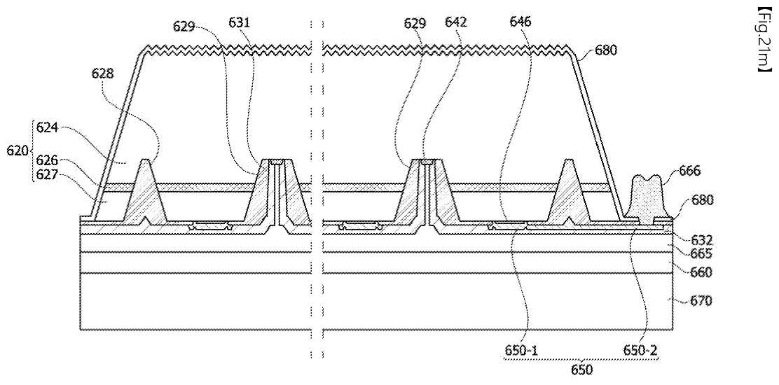

FIGS. 21A to 21M are sequence diagrams for describing a method of manufacturing the semiconductor device according to the sixth embodiment.

The method of manufacturing the semiconductor device according to the sixth embodiment includes growing a semiconductor structure, disposing a first recess and a second recess, which is located inward from the first recess, in the semiconductor structure, disposing a first insulating layer on the semiconductor structure, disposing a first electrode in the second recess and a second electrode on the semiconductor structure, disposing a first conductive layer on the semiconductor structure and the second electrode, disposing a second insulating layer on the first insulating layer and the first conductive layer, and disposing a second conductive layer, a bonding layer, and a substrate on the second insulating layer.

Further, the disposing of the first insulating layer may include disposing a first insulating layer including a groove on an upper surface thereof, disposing a photoresist in the groove, etching the first insulating layer to remove the groove, and removing the photoresist.

Each operation will be described below in detail with reference to FIGS. 21A to 21M.

Referring to FIG. 21A, a semiconductor structure 620 may be grown. The semiconductor structure 620 may be grown on a first temporary substrate T. For example, a first conductive semiconductor layer 624, an active layer 626, and a second conductive semiconductor layer 627 may be grown on the first temporary substrate T.

The first temporary substrate T may be a growth substrate. For example, the first temporary substrate T may be made of at least one selected from among sapphire (Al₂O₃), SiC, GaAs, GaN, ZnO, Si, GaP, InP, and Ge, but the present invention is not limited to such a material.

Further, the semiconductor structure 620 may be formed using, for example, an MOCVD method, a CVD method, a PECV method, an MBE method, a HVPE method, or the like, but the present invention is not limited thereto.

Descriptions of the first conductive semiconductor layer 624, the active layer 626, and the second conductive semiconductor layer 627 may be the same as described above.

Referring to FIG. 21B, a first recess 628 and a second recess 629 may be disposed in the semiconductor structure 620. The first recess 628 and the second recess 629 may be formed by various etching methods as described above.

Specifically, the first recess 628 may be disposed along an edge of the semiconductor structure 620. Thus, as described above, the semiconductor structure 620 may be divided into a first region and a second region by the first recess 628.

In addition, as in the first recess 628, the second recess 629 is disposed to pass through the second conductive semiconductor layer 627 and the active layer 626 and to pass through even a partial region of the first conductive semiconductor layer 624 in the semiconductor structure 620.

Further, the second recess 629 may be formed simultaneously with the first recess 628 by etching. As a result, the first recess 628 and the second recess 629 are formed by one process, and thus processes may be minimized. Further, as described above, the first recess 628 and the second recess 629 may have the same inclination angle and the same thickness in a vertical direction. However, the first recess 628 and the second recess 629 may have different widths in a horizontal direction. For example, a minimum width W6 of the first recess 628 may be less than a minimum width W1 of the second recess 629. However, the present invention is not limited to such a process, and the first recess 628 and the second recess 629 may be disposed in the semiconductor structure 620 by different etching processes.

Referring to FIG. 21C, a first insulating layer 631 may be disposed on the semiconductor structure 620. In this case, the first insulating layer 631 may have grooves G1 and G2, which respectively face the first recess 628 and the second recess 629, in an upper surface thereof along the shapes of the first recess 628 and the second recess 629. That is, the upper surface of the first insulating layer 631 may extend downward on the first recess 628 and the second recess 629.

Further, a height ratio between a height hj of the first insulating layer 631 and a height h1 of each of the first recess 628 and the second recess 629 may be 1:1.5 to 1:3. When the height ratio is less than 1:1.5, the upper surface of the second insulating layer 632 is not flat, and thus there is a limitation that voids are generated between the upper surface of the second insulating layer 632 and a bonding layer to be described below. That is, the reliability of the semiconductor device may be degraded. In addition, when the height ratio is greater than 1:3, there is a problem of increasing process cost and time at the time of etching.

Referring to FIG. 21D, a photoresist PR may be disposed on the grooves G1 and G2 of the first insulating layer 631. The photoresist PR may be applied to the inside of each of the grooves G1 and G2 of the first insulating layer 631 and onto the first insulating layer 631. In an embodiment, the photoresist PR may include a first photoresist PR1 disposed in the groove G1 above the first recess 628 and a second photoresist PR2 disposed in the groove G2 above the second recess 629. The first photoresist PR1 and the second photoresist PR2 may be located in the first recess 628 and the second recess 629, respectively, to form a predetermined pattern.

The first photoresist PR1 may be smaller in diameter and height than the second photoresist PR2.

Referring to FIG. 21E, first etching may be performed on the photoresist PR. Since the first etching is performed on the photoresist PR, the same etching rate (E1) may be applied over the entire surface. Here, the etching may be performed by various etching methods, for example, wet or dry etching may be applied.

In addition, the first photoresist PR1 and the second photoresist PR2 may remain and the first insulating layer 631 may be exposed by etching.

Referring to FIG. 21F, secondary etching may be performed so that the grooves G1 and G2 of the first insulating layer 631 are removed.

Specifically, the etching may be performed on the first photoresist PR1 and the second photoresist PR2 at a first etching rate (E2 and E3). However, the etching may be performed on the first insulating layer 631 at a second etching rate (E4). In this case, the first etching rate and the second etching rate are different from each other, and the first etching rate may be higher than the second etching rate. However, this may be changed according to the materials of the first photoresist PR1, the second photoresist PR2, and the second insulating layer 632.

A height difference in the upper surface of the first insulating layer 631 may be reduced by the etching. However, the upper surface of the first insulating layer 631 above the first recess 628 and the second recess 629 may have the height difference as described above. However, the height difference is less than the height of each of the first recess 628 and the second recess 629, and thus the upper surface of the second insulating layer 632 may be flat above the first recess 628 and the second recess 629.

Accordingly, gaps (voids) may be prevented from being generated at an interface with an element disposed on the first insulating layer 631. In addition, the generation of voids is suppressed so that bonding force, thermal resistance, and the like between the first insulating layer 631 and the element thereon may be improved, thereby improving the reliability of the semiconductor device.

Further, when the photoresist remains in the process, the photoresist may be removed by a stripper or the like, but the present invention is not limited thereto. In addition, the stripper may include a fluorine-based compound having chemical stability. However, the present invention is not limited to such a material.

Referring to FIG. 21G, the first insulating layer 631 inside the second recess 629 may be etched to expose the first conductive semiconductor layer 624. Further, a portion of the first insulating layer 631, which is located inward from the first recess 628 and on an upper surface of the semiconductor structure 620, may be etched to partially expose the second conductive semiconductor layer 627.

In addition, a first electrode 642 may be disposed on the exposed first conductive semiconductor layer 624. Further, a second electrode 646 may be disposed on the exposed second conductive semiconductor layer 627. However, the present invention is not limited to such an order, and before the first insulating layer 631 is disposed, the first electrode 642 and the second electrode 646 may be disposed first.

Referring to FIG. 21H, a first conductive layer 650 may be disposed on the first insulating layer 631 and the second electrode 646. In this case, the first conductive layer 650 may be disposed to surround the second electrode 646. Accordingly, the first conductive layer 650 may be in contact with the second electrode 646 to be electrically connected to the second electrode 646.

Further, the first insulating layer 631 may electrically insulate the first conductive layer 650 from the first conductive semiconductor layer 624.

The first conductive layer 650 may be partially disposed on the first recess 628 and may extend toward the edge of the semiconductor structure 620. However, as described above, the first conductive layer 650 may extend toward an electrode pad and may have a region that does not overlap the first recess 628 in the vertical direction.

Further, the first conductive layer 650 may be etched so as not to be exposed to an outer side surface of the semiconductor device.

Referring to FIG. 21I, a second insulating layer 632 may be disposed on the semiconductor structure 620. In addition, the second insulating layer 632 may be disposed to surround the first conductive layer 650. That is, an upper surface of the second insulating layer 632 may extend downward on the first recess 628 and the second recess 629.

Further, the second insulating layer 632 may be disposed on the first insulating layer 631, the first conductive layer 650, and the first electrode 642 to surround the first insulating layer 631 and the first electrode 642. With such a configuration, even when a crack is generated in the first insulating layer 631, the second insulating layer 632 may secondarily protect the semiconductor structure 620.

In addition, the second insulating layer 632 may include a through hole GH to expose a portion of an upper surface of the first electrode 642. The through hole GH may be located on the first electrode 642 and may extend in the vertical direction. For example, the through hole GH may be disposed to overlap the first electrode 642 in the vertical direction.

Referring to FIG. 21J, a second conductive layer 665 may be disposed on the second insulating layer 632. The second conductive layer 665 may be disposed on the exposed upper surface of the first electrode 642. Thus, the second conductive layer 665 may be electrically connected to the first electrode 642. In addition, the second insulating layer 632 may electrically insulate the second electrode 646 from the second conductive layer 665.

Referring to FIG. 21K, a bonding layer 660 and a second substrate T′ may be disposed on the second conductive layer 665.

First, the bonding layer 660 may include a conductive material. As an example, the bonding layer 660 may include a material selected from the group consisting of gold, tin, indium, aluminum, silicon, silver, nickel, and copper, or an alloy thereof.

In addition, the second substrate T′ may be the same substrate as the substrate 670 in FIG. 1. Thus, as illustrated in FIG. 1, the second substrate T′ may be made of a conductive material. As an example, the second substrate T′ may include a metal or a semiconductor material. The second substrate T′ may include a metal having high electrical conductivity and/or thermal conductivity. In this case, heat generated during an operation of the semiconductor device may be rapidly discharged to the outside. In addition, when the second substrate T′ is made of a conductive material, the first electrode 642 may be supplied with a current from the outside through the second substrate T′.

The second substrate T′ may include a material selected from the group consisting of silicon, molybdenum, tungsten, copper, and aluminum or an alloy thereof.

Further, the bonding layer 660 and the second substrate T′ may be disposed on the second insulating layer 632 and may be flat along the upper surface of the second insulating layer 632. As a result, the generation of voids between the interfaces is suppressed so that the delamination caused by heat is suppressed, thereby improving the bonding force between each element of the semiconductor device.

In addition, referring to FIG. 21L, the first temporary substrate T may be separated from the semiconductor structure 620. For example, the first temporary substrate T may be separated from the semiconductor structure 620 by irradiating laser light onto the first temporary substrate T. However, the present invention is not limited to such a manner.

Referring to FIG. 21M, a passivation layer 680 may be disposed on upper and side surfaces of the semiconductor structure 620. As described above, the passivation layer 680 may have a thickness of 200 nm to 500 nm. When the thickness is greater than or equal to 200 nm, a device may be protected from external moisture or foreign substances, thereby improving the electrical and optical reliability of the device. When the thickness is less than or equal to 500 nm, it is possible to reduce stress applied to the semiconductor device, to prevent a decrease in optical and electrical reliability of the semiconductor device, and to reduce costs of the semiconductor device, which are increased by an increase in a processing time of the semiconductor device. However, the present invention is not limited to such a configuration.

Further, before the passivation layer 680 is disposed, uneven portions may be formed on the upper surface of the semiconductor structure 620. The uneven portions enable extraction efficiency of light emitted from the semiconductor structure 620 to be improved. Heights of the uneven portions may be differently adjusted according to a wavelength of light generated in the semiconductor structure 620. In addition, an electrode pad 666 may be formed through a pattern.

The semiconductor device may be used as a light source of a lighting system, a light source of an image display apparatus, or a light source of a lighting apparatus. That is, the semiconductor device may be disposed in a case and applied to various electronic devices configured to provide light. As an example, when the semiconductor device is mixed with a red-green-blue (RGB) phosphor and used, white light with a high color rendering index (CRI) may be implemented.

The above-described semiconductor device may be configured as a light-emitting device package and used as a light source of a lighting system. For example, the semiconductor device may be used as a light source of an image display apparatus or a light source of a lighting apparatus.

When used as a backlight unit of an image display apparatus, the semiconductor apparatus may be used as an edge-type backlight unit or a direct-type backlight unit. When used as a light source of a lighting apparatus, the semiconductor device may be used as a lamp or bulb type. The semiconductor device may also be used as a light source for a mobile terminal.

A light-emitting device includes a laser diode in addition to the light-emitting diode described above.

Like the light-emitting device, the laser diode may include a first conductive semiconductor layer, an active layer, and a second conductive semiconductor layer that have the above-described structures. In addition, the laser diode may utilize an electroluminescence phenomenon in which light is emitted when current flows after bonding a p-type first conductive semiconductor and an n-type second conductive semiconductor but has a difference in the directionality and phase of the emitted light. That is, the laser diode uses stimulated emission and constructive interference phenomena so that light having a specific single wavelength (monochromatic beam) may be emitted at the same phase and in the same direction. Due to these characteristics, the laser diode may be used for optical communication or medical equipment, semiconductor processing equipment, or the like.

A light-receiving device may include, for example, a photodetector, which is a kind of transducer configured to detect light and convert the intensity of the light into an electric signal. Such a photodetector includes a photocell (silicon or selenium), a photoconductor element (cadmium sulfide or cadmium selenide), a photodiode (PD) (for example, a PD having a peak wavelength in a visible blind spectral region or a true blind spectral region), a phototransistor, a photomultiplier tube, a phototube (vacuum or gas-filled), an infra-red (IR) detector, and the like, but the embodiment is not limited thereto.

Further, the semiconductor device such as the photodetector may generally be manufactured using a direct bandgap semiconductor having a high photoconversion efficiency. Alternatively, the photodetector has various structures and the most common structure may include a pin-type photodetector using a p-n junction, a Schottky-type photodetector using a Schottky junction, a metal-semiconductor-metal (MSM)-type photodetector, or the like.

Like the light-emitting device, the photodiode may include a first conductive semiconductor layer, an active layer, and a second conductive semiconductor layer that have the above-described structures and may be formed as a p-n junction or pin structure. The photodiode operates when a reverse bias or a zero bias is applied, and when light is incident on the photodiode, electrons and holes are generated such that current flows. In this case, the magnitude of current may be approximately proportional to the intensity of light incident on the photodiode.

A photocell or solar cell, which is a kind of photodiode, may convert light into current. Like the light-emitting device, the solar cell may include a first conductive semiconductor layer, an active layer, and a second conductive semiconductor layer that have the above-described structures.

Further, the solar cell may be used as a rectifier of an electronic circuit through the rectification characteristics of a general diode using a p-n junction and may be applied to an ultra-high frequency circuit and then may be applied to an oscillation circuit or the like.

Further, the above-described semiconductor device is not necessarily implemented only with semiconductors, and may further include a metal material in some cases. For example, the semiconductor device such as a light-receiving device may be implemented using at least one of Ag, Al, Au, In, Ga, N, Zn, Se, P, and As and may be implemented using an intrinsic semiconductor material or a semiconductor material doped with a p-type dopant or an n-type dopant.

1. A semiconductor device comprising:
a substrate;
a semiconductor structure including a first conductive semiconductor layer and a second conductive semiconductor layer, which are disposed on the substrate, an active layer disposed between the first conductive semiconductor layer and the second conductive semiconductor layer, and a recess passing through the second conductive semiconductor layer and the active layer;
a first electrode disposed on the semiconductor structure and electrically connected to the first conductive semiconductor layer;
a second electrode disposed on the semiconductor structure and electrically connected to the second conductive semiconductor layer;
a first pad disposed on the first electrode; and
a second pad disposed on the second electrode,
wherein the recess divides the second conductive semiconductor layer and the active layer into an active region and an inactive region,
the recess is extended and disposed to surround the active region, and
the second pad is disposed on the second electrode to extend to an upper portion of the recess.

2. The semiconductor device of claim 1, wherein
the recess includes a bottom surface, an inner inclined surface connected to the bottom surface and adjacent to the active region, and an outer inclined surface connected to the bottom surface and facing the inner inclined surface, and
one end of the second pad is disposed to extend on the inner inclined surface of the recess.

3. The semiconductor device of claim 2, wherein the one end of the second pad is disposed to extend on the bottom surface and the outer inclined surface of the recess.

4. The semiconductor device of claim 3, wherein
the second pad is disposed to extend on the second conductive semiconductor layer in the inactive region, and
the one end of the second pad is disposed between the recess and an outermost side surface of the second conductive semiconductor layer.

5. The semiconductor device of claim 1, wherein
the semiconductor structure includes a concave portion to which the first conductive semiconductor layer is exposed, and
the concave portion is disposed to extend from an outer side of the inactive region.

6. The semiconductor device of claim 1, wherein a width ratio of a maximum width of the recess in a horizontal direction and a maximum width of the second conductive semiconductor layer in the inactive region in the horizontal direction is in a range of 1:0.5 to 1:5.

7. The semiconductor device of claim 1, further comprising:
a first bump disposed on the first pad; and
a second bump disposed on the second pad to be spaced apart from the first bump.

8. The semiconductor device of claim 5, wherein
the first electrode is disposed on the first conductive semiconductor layer in the concave portion, and
the second electrode is disposed on the second conductive semiconductor layer in the active region.

9. The semiconductor device of claim 5, further comprising a first insulating layer disposed on the semiconductor structure,
wherein the first insulating layer is disposed to extend on the first conductive semiconductor layer in the recess and the concave portion from the second conductive semiconductor layer in the active region and to cover the active layer and the exposed second conductive semiconductor layer.

10. The semiconductor device of claim 9, wherein
the first insulating layer is disposed to extend to the first electrode,
the inactive region is disposed to surround the recess,
the active region is electrically connected to the second electrode, and
the inactive region is electrically separated from the second electrode.

11. The semiconductor device of claim 8, further comprising a first insulating layer disposed on the semiconductor structure,
wherein the first insulating layer is disposed to extend on the first conductive semiconductor layer in the recess and the concave portion from the second conductive semiconductor layer in the active region and to cover the active layer and the exposed second conductive semiconductor layer.
